(19) United States
(12) Patent Application Publication
(10) Pub. No.: US 2025/0129242 A1
(43) Pub. Date: Apr. 24, 2025

(54) RESIN COMPOSITION AND USES OF THE SAME

(71) Applicant: TAIWAN UNION TECHNOLOGY CORPORATION, ZHUBEI CITY (TW)

(72) Inventors: JEN-CHI CHIANG, ZHUBEI CITY (TW); MENG-HUEI CHEN, ZHUBEI CITY (TW); WEI-HSIN HUANG, ZHUBEI CITY (TW)

(73) Assignee: TAIWAN UNION TECHNOLOGY CORPORATION, ZHUBEI CITY (TW)

(21) Appl. No.: 18/428,336

(22) Filed: Jan. 31, 2024

(30) Foreign Application Priority Data
Oct. 19, 2023 (TW) 112140049

(51) Int. Cl. C08L 51/00; C08J 5/24; C08K 3/36; C08K 5/3492

(52) U.S. Cl. CPC C08L 51/003; C08J 5/244; C08K 3/36; C08K 5/34924; C08J 2353/00; C08L 2203/20

(57) ABSTRACT

A resin composition is provided. The resin composition comprises:
(A) a compound having a structure of formula (I); and

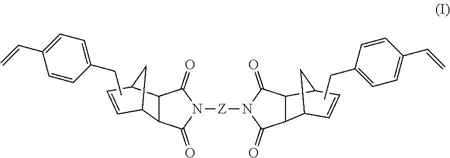

(B) a component having ethylenically unsaturated double bond(s), which is selected from the group consisting of a compound having a structure of formula (II), a compound having a structure of formula (III), and combinations thereof,

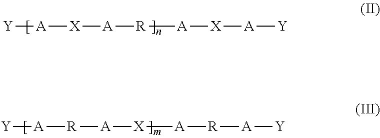

wherein Z, A, R, X, Y, m, and n are as defined in the specification.

### CLAIM FOR PRIORITY

This application claims the benefit of Taiwan Patent Application No. 112140049 filed on Oct. 19, 2023, the subject matters of which are incorporated herein in their entirety by reference.

### BACKGROUND OF THE INVENTION

### Field of the Invention

The present invention provides a resin composition, especially a resin composition comprising a compound having a specific structure and a component having ethylenically unsaturated double bond(s). The resin composition of the present invention can be used in combination with a reinforcing material to constitute a prepreg or be used as a metal foil adhesive to prepare a metal-clad laminate and a printed circuit board (PCB).

### Descriptions of the Related Art

As a result of the development of high-frequency and high-speed transmission electronic products, the miniaturization of electronic elements, and the high-density wiring in substrates, there are higher demands for the physicochemical properties of the electronic materials used. Conventional resin compositions with epoxy resin as the main component have failed to meet these requirements and are thus being replaced by resin compositions with polyphenylene ether (PPE) as the main component. For example, U.S. Pat. No. 6,352,782 B2 (Applicant: General Electric (GE)) discloses a thermosetting polyphenylene ether resin composition, which comprises an end capped polyphenylene ether with unsaturated groups (mPPE) and a cross-linkable unsaturated monomer compound. In this document, triallyl isocyanurate (TAIC) is used as a monomer cross-linking agent together with an acrylate capped polyphenylene ether to form a thermosetting composition to meet the requirements for high-frequency electrical properties.

However, the electrical properties provided by existing PPE resin are still unsatisfactory and require further improvement. Additionally, modern electronic products must rapidly transmit high-frequency signals with high capacity. The transmission of signals generates a substantial amount of heat, leading to signal loss or delay. Consequently, the thermal resistance properties provided by existing PPE resin are becoming inadequate to meet industrial requirements.

### SUMMARY OF THE INVENTION

Given the aforementioned technical problems, the present invention provides a resin composition that uses a compound having a specific structure and a component having ethylenically unsaturated double bond(s). The electronic materials prepared from the cured product of the resin composition can exhibit high glass transition temperature (Tg), low coefficient of thermal expansion (CTE), low dielectric constant (Dk), low dielectric loss factor (Df), excellent aging resistance (indicated by Df variation), excellent heat resistance after moisture absorption, excellent processing stability (indicated by filling property and tackiness), excellent adhesion to a metal layer (high peeling strength), and low water absorption.

Therefore, an objective of the present invention is to provide a resin composition, which comprises:
(A) a compound having a structure of formula (I); and

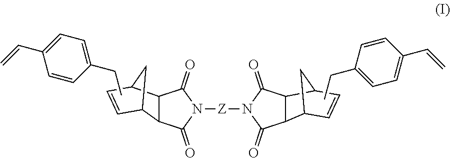

(B) a component having ethylenically unsaturated double bond(s), which is selected from the group consisting of a compound having a structure of formula (II), a compound having a structure of formula (III), and combinations thereof,

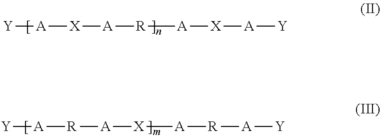

wherein,
Z is a divalent organic group;
each A is independently —O—, —S—, or —N(R₁)—, wherein R₁ is H, a C1-C20 hydrocarbyl, a C1-C20 halogenated hydrocarbyl, or a group formed by substituting a part of the C1-C20 hydrocarbyl or halogenated hydrocarbyl with at least one of O and S;
each R is independently an unsubstituted or substituted divalent nitrogen-containing heteroaromatic ring;
each X is independently

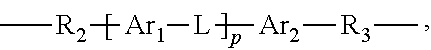

wherein R₂ and R₃ are independently a direct bond or a C1-C4 alkylene, Ar₁ and Ar₂ are independently an unsubstituted or substituted divalent aromatic hydrocarbyl, L is a direct bond, —O—, —S—, —N(R₄)—, —C(O)—O—, —C(O)—NH—, —S(O)—, S(O)₂—, —P(O)—, a C1-C20 alkylene, a C1-C20 halogenated alkylene, a divalent cardo structure, or an unsubstituted or substituted divalent C5-C30 alicyclic hydrocarbyl, R₄ is H, a C1-C20 hydrocarbyl, or a C1-C20 halogenated hydrocarbyl, p is an integer of 0-5, and each Ar₁ can be identical or different when p is 2 or more;
each Y is independently a group containing ethylenically unsaturated double bond(s);
m is an integer of 1-100; and
n is an integer of 1-100.

In some embodiments of the present invention, the component (B) having ethylenically unsaturated double bond(s) is selected from the group consisting of a compound having a structure of formula (IIa), a compound having a structure of formula (IIIa), and combinations thereof,

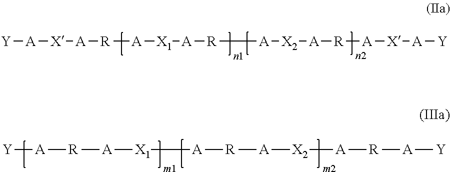

wherein,
R, A and Y of formulas (IIa) and (IIIa) have the same definition as in formulas (II) and (III);

X₁ and X₂ each have the same definition as X of formulas (II) and (III), and X₁ and X₂ are different from each other;
X′ is X₁ or X₂;
n₁ and n₂ are independently an integer of 0-50, and a sum of n₁ and n₂ is less than 100; and
m₁ and m₂ are independently an integer of 0-50, with the proviso that m₁ and m₂ are not 0 at the same time.

In some embodiments of the present invention, Z in formula (I) is

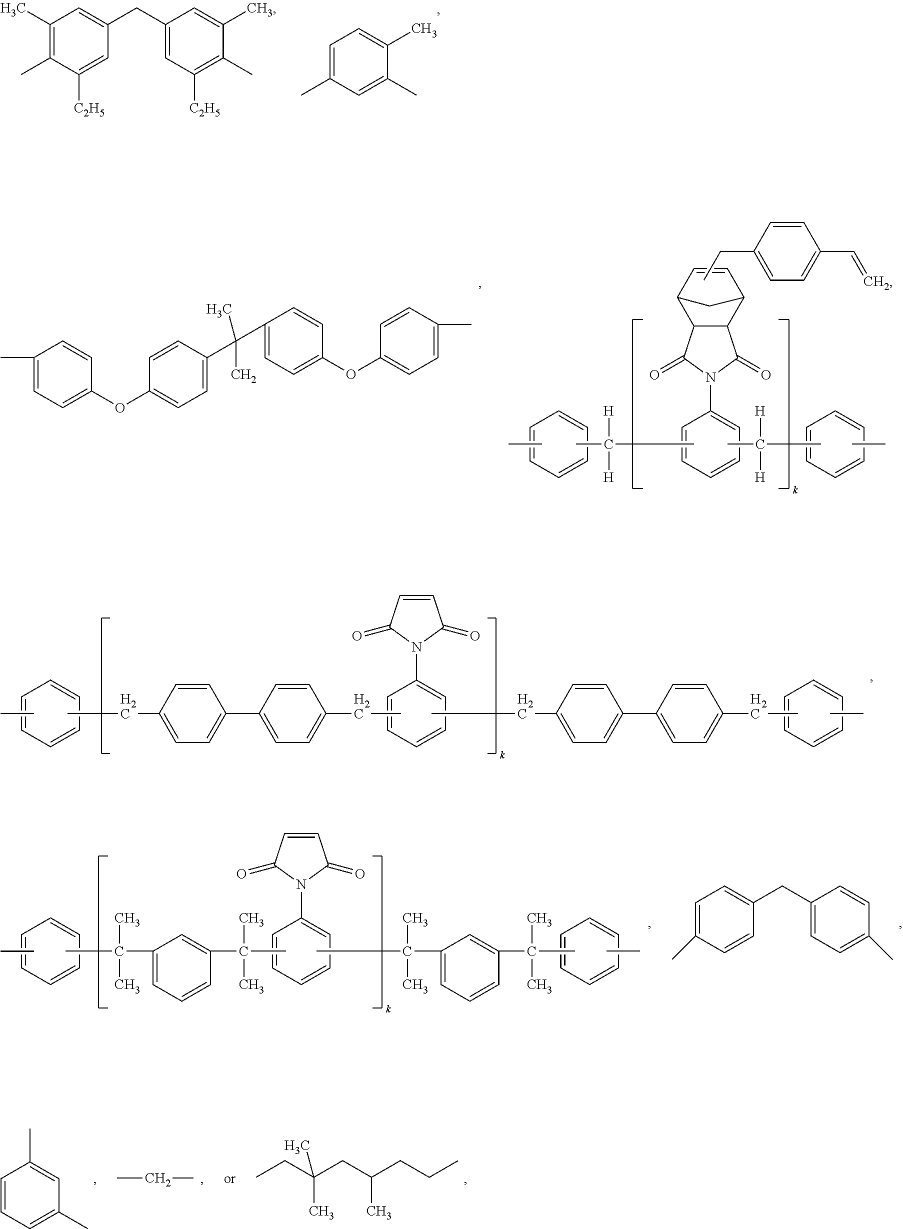

wherein k is an integer of 1-5.

In some embodiments of the present invention, R in formulas (II), (III), (IIa), and (IIIa) is each independently an unsubstituted or substituted divalent nitrogen-containing heteroaromatic ring, and the nitrogen-containing heteroaromatic ring is a pyrrole ring, a pyridine ring, a pyrimidine ring, a pyridazine ring, a pyrazine ring, a triazine ring, a quinoline ring, an isoquinoline ring, a quinoxaline ring, a phthalazine ring, a quinazoline ring, a naphthyridine ring, a carbazole ring, an acridine ring, or a phenazine ring; preferably a pyridine ring, a pyrimidine ring, a pyridazine ring, a pyrazine ring, or a triazine ring.

In some embodiments of the present invention, Ar₁ and Ar₂ are independently an unsubstituted or substituted divalent aromatic hydrocarbyl, wherein the divalent aromatic hydrocarbyl is phenylene, naphthylene, anthracenylene, or biphenylene, and each Ar₁ can be identical or different.

In some embodiments of the present invention, L is a C1-C10 alkylene, a C1-C10 halogenated alkylene,

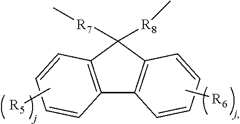

or an unsubstituted or substituted divalent C5-C30 alicyclic hydrocarbyl,
wherein,

R₅ and R₆ are each independently F or a C1-C20 linear hydrocarbyl;
R₇ and R₈ are independently a direct bond, an unsubstituted or substituted linear hydrocarbylene, or an unsubstituted or substituted alicyclic hydrocarbylene; and
j is an integer of 0-4.

In some embodiments of the present invention, Y in formulas (II), (III), (IIa), and (IIIa) is each independently 2-isopropenylphenyl, 3-isopropenylphenyl, 4-isopropenylphenyl, 2-allylphenyl, 3-allylphenyl, 4-allylphenyl, 2-methoxy-4-allylphenyl, 4-(1-propenyl)-2-methoxyphenyl, 4-vinylbenzyl, 3-vinylbenzyl, 2-vinylbenzyl, allyl, acryloyl, methacryloyl, or methallyl.

In some embodiments of the present invention, the weight ratio of the compound (A) having a structure of formula (I) to the component (B) having ethylenically unsaturated double bond(s) is 1:9 to 1:1.

In some embodiments of the present invention, the resin composition further comprises an additive selected from the group consisting of a catalyst, a cross-linking agent, an elastomer, a filler, a dispersing agent, a toughener, a viscosity modifier, a flame retardant, a plasticizer, a coupling agent, and combinations thereof.

The catalyst can be selected from the group consisting of dicumyl peroxide, tert-butyl peroxybenzoate, di-tert-amyl peroxide (DTAP), isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide (BPO), 1,1-bis(tert-butylperoxy)-3,3,5-trimethylcyclohexane, 4,4-di(tert-butylperoxy)butyl valerate, 2,5-dimethyl-2,5-di(tert-butylperoxy)hexane, 2,5-dimethyl-2,5-di(tert-butylperoxy)-3-hexyne, and combinations thereof.

The cross-linking agent can be selected from the group consisting of a polyfunctional allylic compound, a polyfuctional acrylate, a polyfuctional acrylamide, a polyfunctional styrenic compound, and combinations thereof.

The elastomer can be selected from the group consisting of polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, a functionally modified derivative of the preceding compounds, and combinations thereof.

The filler can be selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene powders, glass beads, ceramic whiskers, carbon nanotubes, nanosized inorganic powders, and combinations thereof.

Another objective of the present invention is to provide a prepreg prepared by impregnating a substrate with the aforementioned resin composition or by coating the aforementioned resin composition onto a substrate and drying the impregnated or coated substrate.

Yet another objective of the present invention is to provide a metal-clad laminate prepared by laminating the aforementioned prepreg and a metal foil or by coating the aforementioned resin composition onto a metal foil and drying the coated metal foil.

A further objective of the present invention is to provide a printed circuit board prepared from the aforementioned metal-clad laminate.

To render the above objectives, technical features, and advantages of the present invention more apparent, the present invention will be described in detail with reference to some embodiments hereinafter.

### BRIEF DESCRIPTION OF THE DRAWINGS

Not applicable.

### DESCRIPTION OF THE PREFERRED EMBODIMENTS

Hereinafter, some embodiments of the present invention will be described in detail. However, the present invention may be embodied in various embodiments, and the protection scope of the present invention should not be limited to those described in the specification.

Unless otherwise specified, the expressions “a,” “the,” or the like recited in the specification and in the claims should include both the singular and the plural forms.

Unless otherwise specified, when specifying the amount of components in a solution, mixture, or composition in the specification and the claims, it is calculated based on the total weight excluding the solvent.

By using a compound (A) having a specific structure together with a specific component (B) having ethylenically unsaturated double bond(s) in the resin composition of the present invention, the electronic material prepared from the cured product of the resin composition of the present invention can exhibit excellent glass transition temperature (Tg), coefficient of thermal expansion (CTE), dielectric constant (Dk), dielectric loss factor (Df), aging resistance (indicated by variation of Df), heat resistance after moisture absorption (PCT), processing stability (indicated by filling property and tackiness), adhesion to a metal layer (high peeling strength), and resistance to water absorption. The resin composition of the present invention and its applications are described in detail below.

### 1. Resin Composition

The resin composition of the present invention comprises (A) a compound having a structure of formula (I) and (B) a component having ethylenically unsaturated double bond(s) as essential components. It may further comprise optional components. The detailed descriptions of these components are as follows.

### 1.1. (A) Compound Having Structure of Formula (I)

The compound (A) has a structure of formula (I) below. The compound (A) contains unsaturated functional groups, allowing it to undergo a cross-linking reaction with the component (B) having ethylenically unsaturated double bond(s), as described later, forming a stereo network structure.

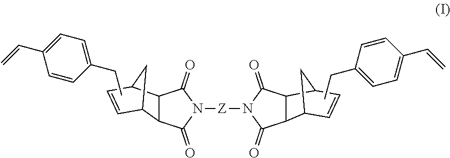

In formula (I), Z is a divalent organic group, and examples of the divalent organic group include, but are not limited to, 3,3′-dimethyl-5,5′-diethyl-4,4′-diphenylmethyl

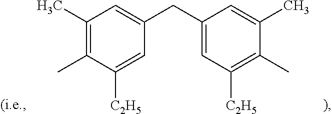

### 4-methyl-1,3-phenylene

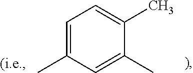

bisphenol A diphenyl ether group

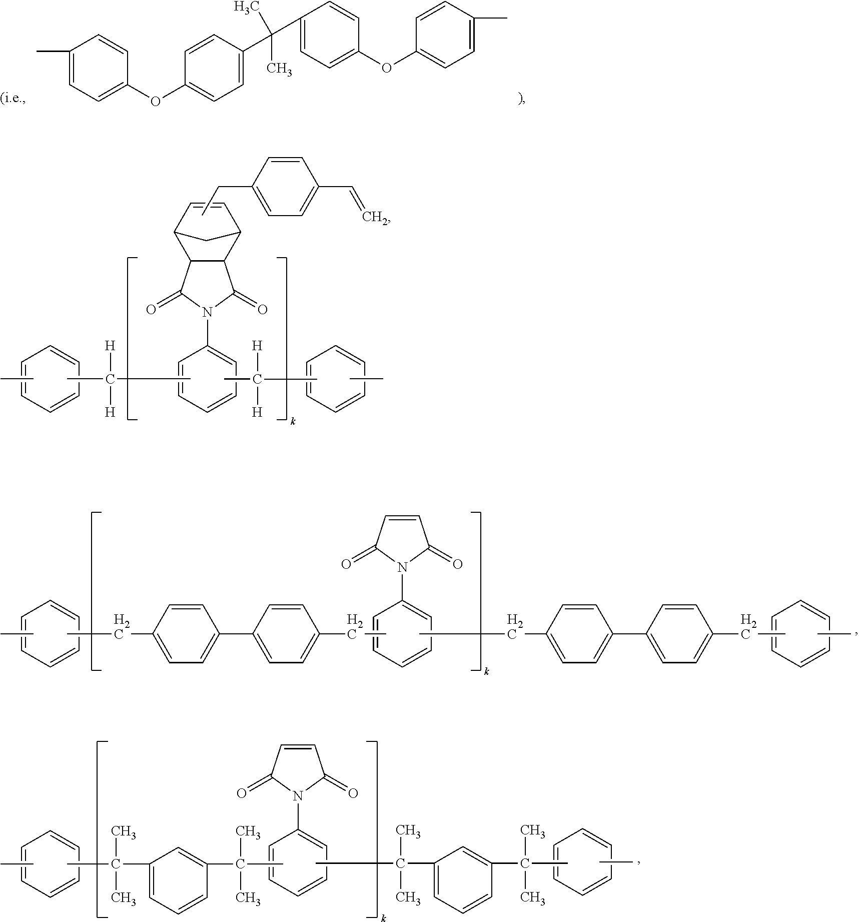

4,4′-diphenylmethyl

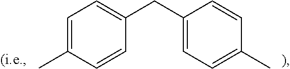

m-phenylene

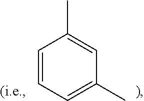

methylene (i.e. —CH₂—), or (2,2,4-trimethyl)hexylene

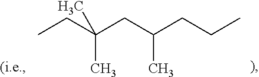

wherein k is an integer of 1 to 5.

The compound (A) having a structure of formula (I) contains cross-linkable unsaturated functional groups (i.e. double bonds) that participate in a cross-linking reaction. Therefore, the compound (A) can facilitate a cross-linking reaction, achieving thermosetting through conventional thermal or peroxide catalyst mechanisms. Additionally, the compound (A) can react with any conventional cross-linking agent containing unsaturated group(s). Examples of the cross-linking agent include, but are not limited to, vinyl-containing compounds, allyl-containing compounds, and unsaturated-functional-group-modified PPE (such as an allyl-containing PPE).

The compound (A) having a structure of formula (I) is a terminally vinyl-modified bismaleimide (BMI) derivative. This derivative can be prepared by functionalizing a bismaleimide (BMI) compound. The bismaleimide compound is a compound having a structure of

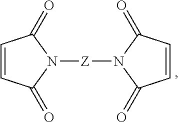

wherein Z has the definition as described above. For example, the compound having the structure of formula (I) can be prepared by using the following method. Initially, as shown in the following chemical equation, a “vinylbenzyl halide (VB) (such as vinylbenzyl chloride)” is reacted with “cyclopentadiene (CPD)” to yield 4-vinylbenzyl substituted cyclopentadiene (VB-CPD).

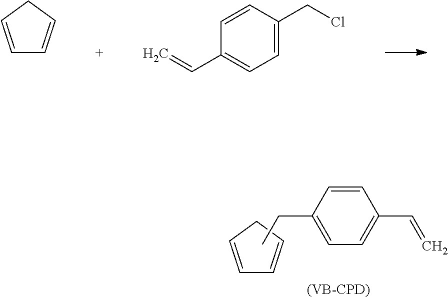

Subsequently, VB-CPD is reacted with a bismaleimide compound to yield a terminally vinyl-modified bismaleimide derivative having the structure of formula (I). Specific examples of preparing the compound having the structure of formula (I) are available in the Synthesis Examples provided in the Example section.

In the resin composition of the present invention, based on the total weight of the resin composition, the amount of the compound (A) having a structure of formula (I) can be 1 wt % to 30 wt %. For example, based on the total weight of the resin composition, the amount of the compound (A) having a structure of formula (I) can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, or 30 wt %, or within a range between any two of the values described herein, but the present invention is not limited thereto.

### 1.2. (B) Component Having Ethylenically Unsaturated Double Bond(s)

### 1.2.1. Embodiments of Formulas (II) and (III)

The component having ethylenically unsaturated double bond(s) is selected from the group consisting of a compound having a structure of formula (II), a compound having a structure of formula (III), and combinations thereof,

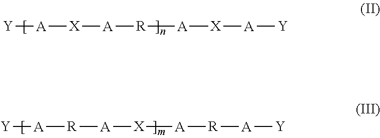

wherein, m is an integer of 1-100, n is an integer of 1-100, and A, R, X, and Y are as defined below.

### [A]

Each A is independently —O—, —S—, or —N(R₁)—, wherein R₁ is H, a C1-C20 hydrocarbyl, a C1-C20 halogenated hydrocarbyl, or a group formed by substituting a part of the C1-C20 hydrocarbyl or halogenated hydrocarbyl with at least one of O and S.

The C1-C20 hydrocarbyl can be a C1-C20 linear hydrocarbyl, a C3-C20 alicyclic hydrocarbyl, or a C6-C20 aromatic hydrocarbyl. Examples of the C1-C20 linear hydrocarbyl include, but are not limited to, methyl, ethyl, n-propyl, isopropyl, n-butyl, isobutyl, sec-butyl, tert-butyl, n-pentyl, vinyl, propenyl, butenyl, ethynyl, propynyl, butynyl, and pentynyl. Examples of the C3-C20 alicyclic hydrocarbyl include, but are not limited to, cyclopropyl, cyclobutyl, cyclopentyl, cyclohexyl, norbornyl, adamantanyl, cyclopropenyl, cyclobutenyl, cyclopentenyl, cyclohexenyl, and norbornenyl. Examples of the C6-C20 aromatic hydrocarbyl include, but are not limited to, phenyl, tolyl, xylyl, naphthyl, anthryl, benzyl, phenethyl, phenylpropyl, and naphthylmethyl.

The C1-C20 halogenated hydrocarbyl refers to a group formed by substituting one or more, or all, of the hydrogen atom(s) in the aforementioned C1-C20 hydrocarbyl with halogen(s) such as fluorine (F), chlorine (C1), bromine (Br), and iodine (I).

Examples of the group formed by substituting a part of the C1-C20 hydrocarbyl or halogenated hydrocarbyl with at least one of O and S include, but are not limited to, a group that is substituted with —O—, —S—, ═O, —S(O)—, or —S(O)₂—.

### [R]

Each R is independently an unsubstituted or substituted divalent nitrogen-containing heteroaromatic ring.

Examples of the nitrogen-containing heteroaromatic ring include, but are not limited to, a pyrrole ring, a pyridine ring, a pyrimidine ring, a pyridazine ring, a pyrazine ring, a triazine ring, a quinoline ring, an isoquinoline ring, a quinoxaline ring, a phthalazine ring, a quinazoline ring, a naphthyridine ring, a carbazole ring, an acridine ring, or a phenazine ring. The nitrogen-containing heteroaromatic ring is preferably a pyridine ring, a pyrimidine ring, a pyridazine ring, a pyrazine ring, or a triazine ring.

The aforementioned “substituted” means that the divalent nitrogen-containing heteroaromatic ring can be substituted with one or more of the following substituents: a halogen, nitro, cyano, amino (including primary amino, secondary amino, and tertiary amino), a C1-C20 hydrocarbyl, a C1-C20 halogenated hydrocarbyl, and a group formed by substituting a part of the C1-C20 hydrocarbyl or halogenated hydrocarbyl with at least one of O and S. Examples of the C1-C20 hydrocarbyl, the C1-C20 halogenated hydrocarbyl, and the group formed by substituting a part of the C1-C20 hydrocarbyl or halogenated hydrocarbyl with at least one of O and S include, but are not limited to, those described above for A in Formulas (II) and (III).

### [X]

Each X in Formulas (II) and (III) is independently

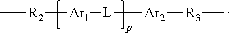

In

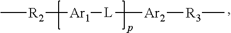

p is an integer of 0-5, and each Ar₁ can be identical or different when p is 2 or more.

R₂ and R₃ are independently a direct bond or a C1-C4 alkylene. Examples of the C1-C4 alkylene include, but are not limited to, methylene, ethylene, n-propylene, isopropylene, n-butylene, and sec-butylene.

Ar₁ and Ar₂ are independently an unsubstituted or substituted divalent aromatic hydrocarbyl. Examples of the divalent aromatic hydrocarbyl include, but are not limited to, phenylene, naphthylene, anthracenylene, and biphenylene. The aforementioned “substituted” means that the divalent aromatic hydrocarbyl can be substituted with one or more of the following substituents: allyl, a halogen, nitro, cyano, amino (including primary amino, secondary amino, and tertiary amino), carboxyl, sulfo, phosphate, phosphonate, a C1-C20 hydrocarbyl, a C1-C20 halogenated hydrocarbyl, a C1-C20 alkoxy, and a C1-C20 alkylthio. Examples of the C1-C20 hydrocarbyl and the C1-C20 halogenated hydrocarbyl include, but are not limited to, those described above for A in Formulas (II) and (III).

L is a direct bond, —O—, —S—, —N(R₄)—, —C(O)—O—, —C(O)—NH—, —S(O)—, S(O)₂—, —P(O)—, a C1-C20 alkylene, a C1-C20 halogenated alkylene, a divalent cardo structure, or an unsubstituted or substituted divalent C5-C30 alicyclic hydrocarbyl.

In —N(R₄)—, R₄ is H, a C1-C20 hydrocarbyl, or a C1-C20 halogenated hydrocarbyl. Examples of the C1-C20 hydrocarbyl and the C1-C20 halogenated hydrocarbyl include, but are not limited to, those described above for A in Formulas (II) and (III).

Examples of the C1-C20 alkylene include, but are not limited to, methylene, ethylene, n-propylene, isopropylene, n-butylenen, sec-butylene, neopentylene, 4-methyl-pentan-2,2-diyl, nonan-1,9-diyl, and decan-1,1-diyl.

Examples of the C1-C20 halogenated alkylene include, but are not limited to, a group formed by substituting one or more, or all, of the hydrogen atoms in the aforementioned C1-C20 alkylene with halogen(s) such as fluorine (F), chlorine (C1), bromine (Br), and iodine (I).

The cardo structure refers to a cyclic side-chain structure which is pendent to the main chain of a molecule. Examples of the cardo structure include, but are not limited to,

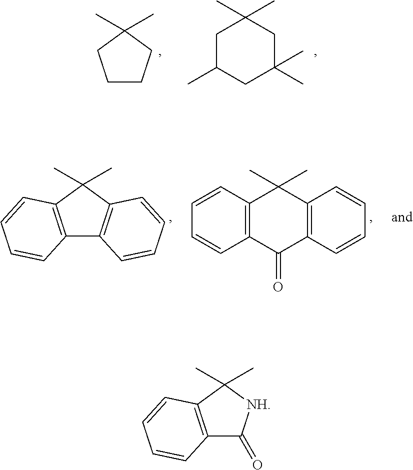

The divalent C5-C30 alicyclic hydrocarbyl can be a divalent C5-C15 monocyclic alicyclic hydrocarbyl, a divalent C5-C15 monocyclic fluorinated alicyclic hydrocarbyl, a divalent C7-C30 polycyclic alicyclic hydrocarbyl, or a divalent C7-C30 polycyclic fluorinated alicyclic hydrocarbyl. Examples of the divalent C5-C15 monocyclic alicyclic hydrocarbyl include, but are not limited to, cyclopentylene, cyclohexylene, cycloheptylene, cyclooctylene, cyclononylene, cyclodecylene, and cyclododecanylene. Examples of the divalent C7-C30 polycyclic alicyclic hydrocarbyl include, but are not limited to, norbornylene, adamantanylene, tricycle [2.2.1.02,6]heptylene, and bornanylene. Examples of the divalent C5-C15 monocyclic fluorinated alicyclic hydrocarbyl and the divalent C7-C30 polycyclic fluorinated alicyclic hydrocarbyl include, but are not limited to, a group formed by substituting one or more, or all, of the hydrogen atoms in the aforementioned divalent C5-C15 monocyclic alicyclic hydrocarbyl and divalent C7-C30 polycyclic alicyclic hydrocarbyl with fluorene atom(s).

The substituted divalent C5-C30 alicyclic hydrocarbyl refers to the divalent C5-C30 alicyclic hydrocarbyl that is substituted with one or more of the following substituents: a halogen, nitro, cyano, amino (including primary amino, secondary amino, and tertiary amino), a C1-C20 hydrocarbyl, a C1-C20 halogenated hydrocarbyl, and a group formed by substituting a part of the C1-C20 hydrocarbyl or halogenated hydrocarbyl with at least one of O and S. Examples of the C1-C20 hydrocarbyl, C1-C20 halogenated hydrocarbyl, and a group formed by substituting a part of the C1-C20 hydrocarbyl or halogenated hydrocarbyl with at least one of O and S include, but are not limited to, those described above for A in Formulas (II) and (III).

In some embodiments of the present invention, L is a C1-C10 alkylene, a C1-C10 halogenated alkylene,

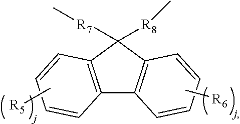

or an unsubstituted or substituted divalent C5-C30 alicyclic hydrocarbyl, wherein R₅ and R₆ are each independently F or a C1-C20 linear hydrocarbyl; R₇ and R₈ are independently a direct bond, an unsubstituted or substituted linear hydrocarbylene, or an unsubstituted or substituted alicyclic hydrocarbylene; and j is an integer of 0-4.

### [Y]

Each Y is independently a group containing ethylenically unsaturated double bond(s), preferably a C3-C50 group containing ethylenically unsaturated double bond(s). Examples of the C3-C50 group containing ethylenically unsaturated double bond(s) include, but are not limited to, 2-isopropenylphenyl, 3-isopropenylphenyl, 4-isopropenylphenyl, 2-allylphenyl, 3-allylphenyl, 4-allylphenyl, 2-methoxy-4-allylphenyl, 4-(1-propenyl)-2-methoxyphenyl, 4-vinylbenzyl, 3-vinylbenzyl, 2-vinylbenzyl, allyl, acryloyl, methacryloyl, and methallyl.

### 1.2.2. Embodiments of Formulas (IIa) and (IIIa)

In some embodiments of the present invention, the component (B) having ethylenically unsaturated double bond(s) comprises at least two different kinds of X. Specifically, the component (B) having ethylenically unsaturated double bond(s) is selected from the group consisting of a compound having a structure of formula (IIa), a compound having a structure of formula (IIIa), and combinations thereof,

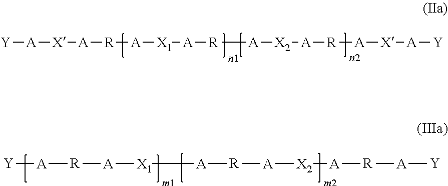

wherein R, A and Y of formulas (IIa) and (IIIa) have the same definition as in formulas (II) and (III); X₁ and X₂ each have the same definition as X of formulas (II) and (III), and X₁ and X₂ are different from each other; X′ is X₁ or X₂; n₁ and n₂ are independently an integer of 0-50, and a sum of n₁ and n₂ is less than 100; and m₁ and m₂ are independently an integer of 0-50, with the proviso that m₁ and m₂ are not 0 at the same time.

### 1.2.3. Synthesis of Component (B)

The synthesis method for the component (B) having ethylenically unsaturated double bond(s) is not particularly limited. Persons having ordinary skill in the art would be able to synthesize the component (B) having ethylenically unsaturated double bond(s) using established chemical mechanisms based on the disclosure within the specification of this application. For example, the component (B) having ethylenically unsaturated double bond(s) of Formula (II) or (III) can be synthesized using the following method: reacting a monomer comprising an R moiety with a monomer comprising an X moiety and a monomer comprising a Y moiety in an organic solvent in the presence of an alkali metal or alkali metal compound; or initially reacting a monomer comprising an R moiety with a monomer comprising an X moiety, followed by a subsequent reaction with a monomer comprising a Y moiety. This process results in the formation of a component (B) where the X moiety and the Y moiety, the X moiety and the R moiety, and the Y moiety and the R moiety are linked by an A moiety, derived from the monomer comprising an X moiety or the monomer comprising a Y moiety.

Examples of the monomer comprising an R moiety include, but are not limited to, the following compounds: a pyrimidine compound such as 4,6,-dichloropyrimidine, 4,6-dibromopyrimidine, 2,4-dichloropyrimidine, 2,5-dichloropyrimidine, 2,5-dibromopyrimidine, 5-bromo-2-chloropyrimidine, 5-bromo-2-fluoropyrimidine, 5-bromo-2-iodopyrimidine, 2-chloro-5-fluoropyrimidine, 2-chloro-5-iodopyrimidine, 2-phenyl-4,6-dichloropyrimidine, 2-methylthio-4,6-dichloropyrimidine, 2-methylsulfonyl-4,6-dichloropyrimidine, 5-methyl-4,6-dichloropyrimidine, 2-amino-4,6-dichloropyrimidine, 5-amino-4,6-dichloropyrimidine, 2,5-diamino-4,6-dichloropyrimidine, 4-amino-2,6-dichloropyrimidine, 5-methoxy-4,6-dichloropyrimidine, 5-methoxy-2,4-dichloropyrimidine, 2-methyl-4,6-dichloropyrimidine, 6-methyl-2,4-dichloropyrimidine, 5-methyl-2,4-dichloropyrimidine, 5-nitro-2,4-dichloropyrimidine, 4-amino-2-chloro-5-fluoropyrimidine, 2-methyl-5-amino-4,6-dichloropyrimidine, and 5-bromo-4-chloro-2-methylthiopyrimidine; a pyridazine compound such as 3,6-dichloropyridazine, 3,5-dichloropyridazine, 4-methyl-3,6-dichloropyridazine; a pyrazine compound such as 2,3-dichloropyrazine, 2,6-dichloropyrazine, 2,5-dibromopyrazine, 2,6-dibromopyrazine, 2-amino-3,5-dibromopyrazine, and 5,6-dicyano-2,3-dichloropyrazine. The aforementioned monomers comprising an R moiety can be used alone or in any combination.

Examples of the monomer comprising an X moiety include, but are not limited to the following compounds: a dihydroxybenzene compound such as p-dihydroxybenzene, m-dihydroxybenzene, o-dihydroxybenzene, phenyl-1,4-dihydroxybenzene; a bisphenol compound such as 9,9-bis(4-hydroxyphenyl)fluorene, 9,9-bis(4-hydroxy-3-methylphenyl)fluorene, 9,9-bis(4-hydroxy-3-phenylphenyl)fluorene, 1,1-bis(4-hydroxyphenyl)-1-phenylethane, bis(4-hydroxyphenyl)diphenylmethane, 2,2-bis(4-hydroxyphenyl)propane, 2,2-bis(4-hydroxy-3-allylphenyl)propane, 2,2-bis(4-hydroxy-3-methylphenyl)propane, 2,2-bis(4-hydroxy-3-phenylphenyl)propane, 4,4′-(1,3-dimethylbutylidene)bisphenol, 1,1-bis(4-hydroxyphenyl) nonane, bis(4-hydroxyphenyl)sulfone, 1,1-bis(4-hydroxyphenyl)cyclohexane, 1,1-bis(4-hydroxyphenyl)-3,3,5-trimethylcyclohexane, 1,1-bis(3-methyl-4-hydroxyphenyl)-3,3,5-trimethylcyclohexane, 1,1-bis(3-cyclohexyl-4-hydroxyphenyl)-3,3,5-trimethylcyclohexane, 1,4-bis [2-(4-hydroxyphenyl)-2-propyl]benzene, 1,3-bis [2-(4-hydroxyphenyl)-2propyl]benzene, 4,4′-cyclododecylidene bisphenol, and 4,4′-decylidene bisphenol; a diol compound such as PRIPLAST 1901, 1838, 3186, 3192, 3197, and 3199 (available from Croda Japan Company). The aforementioned monomers comprising an X moiety can be used alone or in any combination.

Examples of the monomer comprising a Y moiety include, but are not limited to, a monophenol compound such as 4-isopropenylphenol, 3-isopropenylphenol, 2-isopropenylphenol, 4-vinylphenol, 2-allylphenol, 3-allylphenol, and 4-allylphenol; an aliphatic halide such as allyl chloride, 4-(chloromethyl) styrene, 3-(chloromethyl) styrene, and 2-(chloromethyl) styrene; an acid halide such as acryloyl chloride and methacryloyl chloride; an anhydride such as acrylic anhydride, methacrylic anhydride; an unsaturated alcohol such as (4-vinylphenyl) methanol, (3-vinylphenyl) methanol, and (2-vinylphenyl) methanol. The aforementioned monomer comprising a Y moiety can be used alone or in any combination.

Examples of the organic solvent include, but are not limited to, tetrahydrofuran (THF), dioxane, cyclopentyl methyl ether, anisole, phenetole, diphenyl ether, dialkoxy benzene, trialkoxy benzene, N,N-dimethylacetamide (DMAc), N,N-dimethylformamide, N-methyl-2-pyrrolidone, 1,3-dimethyl-2-imidazolidinone, γ-butyrolactone, sulfolane, dimethyl sulfoxide, diethyl sulfoxide, dimethyl sulfone, diethyl sulfone, diisopropyl sulfone, diphenyl sulfone, diphenyl ketone, 2-heptanone, cyclohexanone, methyl ethyl ketone, dichloromethane, chloroform, chlorobenzene, benzene, toluene, and xylene. The aforementioned solvents can be used alone or in any combination.

Examples of the alkali metal or alkali metal compound include, but are not limited to, Li, Na, K, sodium hydride, potassium hydride, lithium hydride, lithium carbonate, sodium carbonate, potassium carbonate, lithium bicarbonate, sodium bicarbonate, and potassium bicarbonate. The aforementioned alkali metal or alkali metal compound can be used alone or in any combination.

The weight average molecular weight (Mw) of the synthesized component (B) having ethylenically unsaturated double bond(s) is preferably 1,000 to 500,000, but the present invention is not limited thereto. The weight average molecular weight (Mw) is determined using gel permeation chromatography (GPC) and calculated by comparison with a standard sample. The unit of the weight average molecular weight (Mw) is “g/mol”.

For specific examples of the synthesis method of the component (B) having ethylenically unsaturated double bond(s), please refer to the Synthesis Examples provided in the Example section.

### 1.2.4. Amount of Component (B)

In the resin composition of the present invention, based on the total weight of the resin composition, the amount of the component (B) having ethylenically unsaturated double bond(s) can be 15 wt % to 40 wt %. For example, based on the total weight of the resin composition, the amount of the component (B) having ethylenically unsaturated double bond(s) can be 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33 wt %, 34 wt %, 35 wt %, 36 wt %, 37 wt %, 38 wt %, 39 wt %, or 40 wt %, or within a range between any two of the values described herein, but the present invention is not limited thereto.

In the resin composition of the present invention, the weight ratio of the compound (A) having a structure of formula (I) to the component (B) having ethylenically unsaturated double bond(s) is preferably 1:9 to 1:1. For example, the weight ratio of the compound (A) having a structure of formula (I) to the component (B) having ethylenically unsaturated double bond(s) can be 1:9, 1:8.5, 1:8, 1:7.5, 1:7, 1:6.5, 1:6, 1:5.5, 1:5, 1:4.5, 1:4, 1:3.5, 1:3, 1:2.5, 1:2, 1:1.5, or 1:1, or within a range between any two of the values described herein. When the weight ratio of the compound (A) having a structure of formula (I) to the component (B) having ethylenically unsaturated double bond(s) is within the aforementioned range, a better inventive efficacy can be obtained.

### 1.3. Optional Components

Without departing from the principle of the present invention, the resin composition of the present invention can further comprise optional components, such as catalysts, cross-linking agents, elastomers, fillers exemplified below and additives known in the art, to adaptively improve the processability of the resin composition during the production process or to improve the physicochemical properties of the electronic materials prepared from the resin composition. Examples of additives known in the art include, but are not limited to, dispersing agents, tougheners, viscosity modifiers, flame retardances, plasticizers, and coupling agents.

### [Catalyst]

In some embodiments of the present invention, the resin composition further comprises a catalyst. A catalyst is a component that can promote a cross-linking reaction. Examples of the catalyst include, but are not limited to, organic peroxides. Examples of the organic peroxides include, but are not limited to, dicumyl peroxide, tert-butyl peroxybenzoate, di-tert-amyl peroxide, isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide, 1,1-bis(tert-butylperoxy)-3,3,5-trimethylcyclohexane, 4,4-di(tert-butylperoxy)butyl valerate, 2,5-dimethyl-2,5-di(tert-butylperoxy)hexane, and 2,5-dimethyl-2,5-di(tert-butylperoxy)-3-hexyne. The aforementioned organic peroxides can be used alone or in any combination. In the appended Examples, α,α′-bis(tert-butylperoxy)diisopropyl benzene (Perbutyl P) is used.

Based on the total weight of the resin composition, the amount of the catalyst can be 0.1 wt % to 1 wt %. For example, based on the total weight of the resin composition, the amount of the catalyst can be 0.1 wt %, 0.2 wt %, 0.3 wt %, 0.4 wt %, 0.5 wt %, 0.6 wt %, 0.7 wt %, 0.8 wt %, 0.9 wt %, or 1.0 wt %, or within a range between any two of the values described herein, but the present invention is not limited thereto.

### [Cross-Linking Agent]

In some embodiments of the present invention, the resin composition further comprises a cross-linking agent. A cross-linking agent is a component containing unsaturated group(s) capable of reacting with the compound (A) having a structure of formula (I) or the component (B) having ethylenically unsaturated double bond(s), resulting in a stereo network structure. The unsaturated group(s) are capable of initiating addition polymerization through light or heat, particularly in the presence of a polymerization initiator. Examples of the unsaturated group(s) include, but are not limited to, vinyl, vinyl benzyl, allyl, acrylic, and methacrylic.

Based on the number of unsaturated group(s) present in the cross-linking agents, the cross-linking agents can be categorized into monofunctional cross-linking agents, having only one unsaturated group in the molecule, and polyfunctional cross-linking agents, having at least two unsaturated groups in the molecule. In the present invention, preference is given to polyfunctional cross-linking agents. Examples of the polyfunctional cross-linking agents include, but are not limited to, a polyfunctional allyl-based compound, a polyfunctional acrylic ester, a polyfunctional acrylic amide, and a polyfunctional styrene-based compound. The aforementioned cross-linking agents can be used alone or in any combination.

A polyfunctional allyl-based compound refers to a compound containing at least two allyls in the molecule. Examples of the polyfunctional allyl-based compound include, but are not limited to, diallyl phthalate, diallyl isophthalate, triallyl trimellitate, triallyl mesate, 1,1′-(1,4-butyl)bis(3,5-diallyl-1,3,5-triazine-2,4,6-trione) (hereinafter “Di-L-DAIC”), triallyl isocyanurate (TAIC), triallyl cyanurate (TAC), and prepolymers of the preceding compounds. In the appended Examples, TAIC or Di-L-DAIC is used.

A polyfunctional acrylic ester refers to a compound containing at least two acrylate groups in the molecule. Examples of the polyfunctional acrylic ester include, but are not limited to, trimethylolpropane tri(meth)acrylate, 1,6-hexanediol di(meth)acrylate, ethyleneglycol di(meth)acrylate, propyleneglycol di(meth)acrylate, 1,3-butanediol di(meth)acrylate, 1,4-butanediol di(meth)acrylate, cyclohexane dimethanol di(meth)acrylate, diethylene glycol di(meth)acrylate, triethylene glycol di(meth)acrylate, and prepolymers containing the preceding compounds.

A polyfunctional styrene-based compound refers to a compound containing at least two alkenyls in the molecule. Examples of the polyfunctional styrene-based compound include, but are not limited to, 1,3-divinylbenzene, 1,4-divinylbenzene, trivinylbenzene, 1,3-diisopropenylbenzene, 1,4-diisopropenylbenzene, 1,2-bis(p-vinylphenyl) ethane, 1,2-bis(m-vinylphenyl) ethane, 1-(p-vinylphenyl)-2-(m-vinylphenyl)-ethane, 1,4-bis(p-vinylphenylethyl)benzene, 1,4-bis(m-vinylphenylethyl)benzene, 1,3-bis(p-vinylphenylethyl)benzene, 1,3-bis(m-vinylphenylethyl)benzene, 1-(p-vinylphenylethyl)-4-(m-vinylphenylethyl)benzene, 1-(p-vinylphenylethyl)-3-(m-vinylphenylethyl)benzene, and prepolymers containing the preceding compounds.

Based on the total weight of the resin composition, the amount of the cross-linking agent can be 0 wt % to 20 wt %. For example, based on the total weight of the resin composition, the amount of the cross-linking agent can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, or within a range between any two of the values described herein, but the present invention is not limited thereto.

### [Elastomer]

In some embodiments of the present invention, the resin composition further comprises an elastomer. In the present invention, the resin composition can further comprise an elastomer to improve the toughness of the prepared electronic material. Examples of the elastomer include, but are not limited to, polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, and a functionally modified derivative of the preceding compounds. Examples of the functionally modified derivative include, but are not limited to, a maleic-anhydride-modified polybutadiene and a maleic-anhydride-modified butadiene-styrene copolymer. The aforementioned elastomers can be used alone or in any combination.

Based on the total weight of the resin composition, the amount of the elastomer can be 0 wt % to 10 wt %. For example, based on the total weight of the resin composition, the amount of the elastomer can be 1 wt %, 2 wt %, 3 wt %, 4 wt %, 5 wt %, 6 wt %, 7 wt %, 8 wt %, 9 wt %, or 10 wt %, or within a range between any two of the values described herein, but the present invention is not limited thereto.

### [Filler]

In some embodiments of the present invention, the resin composition further comprises a filler. Examples of the filler include, but are not limited to, silica (including solid silica and hollow silica), aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene (PTFE) powders, glass beads, ceramic whiskers, carbon nanotubes, and nanosized inorganic powders. The aforementioned fillers can be used alone or in any combination. In the appended Examples, silica is used.

Based on the total weight of the resin composition, the amount of the filler can be 30 wt % to 50 wt %. For example, based on the total weight of the resin composition, the amount of the filler can be 30 wt %, 31 wt %, 32 wt %, 33 wt %, 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, or 50 wt %, or within a range between any two of the values described herein, but the present invention is not limited thereto.

### 1.4. Preparation of Resin Composition

The resin composition of the present invention may be prepared into a varnish for subsequent processing by uniformly mixing the components of the resin composition, including the compound (A) having a structure of formula (I), the component (B) having ethylenically unsaturated double bond(s) and optional components, with a stirrer, and dissolving or dispersing the resultant mixture in a solvent. The solvent can be any inert solvent that can dissolve or disperse the components of the resin composition but does not react with the components of the resin composition. Examples of the solvent include, but are not limited to, toluene, γ-butyrolactone, methyl ethyl ketone, cyclohexanone, butanone, acetone, xylene, methyl isobutyl ketone, N,N-dimethylformamide (DMF), N,N-dimethylacetamide (DMAc), and N-methylpyrolidone (NMP). The mentioned solvents can be used alone or in any combination. The content of the solvent is not particularly limited as long as the components of the resin composition can be uniformly dissolved or dispersed therein. In some embodiments of the present invention, a mixture of methyl ethyl ketone (MEK) and toluene is used as a solvent.

### 2. Prepreg

The present invention also provides a prepreg prepared from the aforementioned resin composition, wherein the prepreg is prepared by impregnating a substrate with the aforementioned resin composition or by coating the aforementioned resin composition onto a substrate and drying the impregnated or coated substrate. Examples of common substrate include, but are not limited to, papers, cloths, or mats made from a material selected from the group consisting of paper fibers, glass fibers, quartz fibers, organic polymer fibers, carbon fibers, and combinations thereof. Examples of the organic polymer fibers include, but are not limited to, high-modulus polypropylene (HMPP) fibers, polyamide fibers, ultra-high molecular weight polyethylene (UHMWPE) fibers, and liquid crystal polymer (LCP) fibers. The cloths made from the material selected from the aforementioned group can be woven or non-woven. In some embodiments of the present invention, 1078 reinforced glass fabric is used as a reinforcing material, and the 1078 reinforced glass fabric is heated and dried at 175° C. for 2 to 15 minutes (B-stage) after being impregnated or coated with the resin composition to provide a semi-cured prepreg.

### 3. Metal-Clad Laminate and Printed Circuit Board

The present invention also provides a metal-clad laminate, which is obtained by laminating the aforementioned prepreg with a metal foil. Specifically, the metal-clad laminate of the present invention comprises a dielectric layer and a metal layer, wherein the dielectric layer is provided from the aforementioned prepreg. The metal-clad laminate can be prepared by superimposing a plurality of the aforementioned prepregs as the dielectric layer, superimposing a metal foil (such as a copper foil, as the metal layer) on at least one external surface of the dielectric layer composed of the superimposed prepregs to provide a superimposed object, and then performing a hot-pressing operation to the superimposed object to obtain the metal-clad laminate. Alternatively, the metal-clad laminate can be prepared by coating the aforementioned resin composition directly on a metal foil and drying the coated metal foil.

The external metal foil of the metal-clad laminate can be further subjected to patterning to provide a printed circuit board.

### 4. Examples

### 4.1. Testing Methods

The present invention is further illustrated by the embodiments hereinafter, wherein the testing instruments and methods are as follows.

### [Peeling Strength Test]

Peeling strength refers to the adhesion of the metal foil, serving as the conductive layer, to the dielectric layer. The peeling strength is expressed by the force required for vertically peeling a ⅛-inch-wide copper foil from the laminate. The unit of the peel strength is lbf/in.

### [Glass Transition Temperature (Tg) Test]

The copper-clad laminate is etched to remove the copper foils on both sides, resulting in an unclad laminate. The unclad laminate undergoes a glass transition temperature (Tg) test. Specifically, the Tg of the unclad laminate is determined using a dynamic mechanical analyzer with model number “Q800”, available from TA Instruments. The testing conditions are as follows: the mode is bending mode, the frequency is 10 Hz, the heating rate is 5° C./min, and the dynamic viscoelasticity is measured during heating from room temperature to 280° C. The Tg is identified as the temperature at which tan δ in the resulting viscoelasticity curve reaches its maximum.

[Coefficient of Thermal Expansion (z-CTE) Test]

A thermomechanical analyzer (TMA) is used to measure the coefficient of thermal expansion of the fully cured resin composition in Z-direction (i.e., in the thickness direction of the substrate) (z-CTE). The testing method is as follows: preparing a sample of the fully cured resin composition sized at 5 mm×5 mm×1.5 mm; setting the conditions to a starting temperature of 30° C., an end temperature of 330° C., a heating rate of 10° C./min, and a load of 0.05 Newton (N); and subjecting the sample to a thermomechanical analysis under the aforementioned conditions in expansion/compression mode. This measures the values of thermal expansion per 1° C. within the range of 30° C. to 330° C., which are then averaged to obtain the z-CTE. The unit of z-CTE is %.

[Dielectric Properties Test (the Dielectric Constant Dk₀ and the Dielectric Loss Factor Df₀ in Dried State)]

The copper-clad laminate is etched to remove the copper foils on both sides, obtaining an unclad laminate with a resin content (RC) of 70% as a test specimen. The test specimen is placed in a dryer at 105° C. and dried for 2 hours to eliminate any moisture. Subsequently, the test specimen is removed from the dryer, placed in a desiccator, and returned to a temperature of 25° C. The dielectric constant and the dielectric loss factor of the test specimen are determined using a cavity perturbation method. Specifically, a network analyzer (ZNA67 from Rohde & Schwarz Company) is used to determine the dielectric constant (Dk₀) and the dielectric loss factor (Df₀) of the dried test specimen at 10 GHz.

[Thermal-Oxidative Aging Resistance Test (Variation of Dielectric Loss Factor (ΔDf₁) after High-Temperature Treatment)]

The copper-clad laminate is etched to remove the copper foils at both sides, obtaining an unclad laminate (RC=70%) as a test specimen. The test specimen is placed in a dryer at 105° C. to dry for 2 hours to eliminate any moisture. Subsequently, the test specimen is removed from the dryer, placed in a desiccator, and returned to a temperature of 25° C. The same testing procedures described in the preceding dielectric properties test section are repeated to determine the dielectric constant (Dk₀) and the dielectric loss factor (Df₀) of the dried test specimen at 10 GHz.

Afterward, the dried test specimen is placed in an oven at 125° C. for 30 days. Subsequently, the same testing procedures described in the preceding dielectric properties test section are repeated to determine the dielectric loss factor (Df₁) of the test specimen after the high-temperature treatment at 10 GHz.

The variation of the dielectric loss factor ΔDf₁ is calculated according to the formula provided below and is assessed according to the specified standard. A smaller variation indicates better thermal-oxidative aging resistance of the test specimen.

$$Δ D {f}_{1} = D {f}_{1} - D {f}_{0}$$

⊚: the variation is 0.0025 or lower.
◯: the variation is higher than 0.0025 and not higher than 0.0030.
Δ: the variation is higher than 0.0030 and not higher than 0.0045.
X: the variation is higher than 0.0045.
   [Damp-Heat Aging Resistance Test (Variation of Dielectric Loss Factor ΔDf₂ after High-Temperature and High-Moisture Treatment)]

The copper-clad laminate is etched to remove the copper foils on both sides, obtaining an unclad laminate (RC=70%) as a test specimen. The test specimen is placed in a dryer at 105° C. and dried for 2 hours to eliminate any moisture. Subsequently, the test specimen is removed from the dryer, placed in a desiccator, and returned to a temperature of 25° C. The same testing procedures described in the preceding dielectric properties test section are repeated to determine the dielectric constant (Dk₀) and the dielectric loss factor (Df₀) of the dried test specimen at 10 GHz.

Afterward, the dried test specimen is exposed to an environment at 85° C. with a relative humidity (RH) of 85% for 30 days. Subsequently, the same testing procedures described in the preceding dielectric properties test section are repeated to determine the dielectric loss factor (Df₂) of the test specimen after the high-temperature and high-moisture treatment at 10 GHz. The variation of dielectric loss factor ΔDf₂ is calculated according to the formula provided below and assessed according to the specified standard. A smaller variation indicates better thermal-oxidative aging resistance of the test specimen.

$$Δ D {f}_{2} = D {f}_{2} - D {f}_{0}$$

⊚: the variation is 0.0025 or lower.
◯: the variation is higher than 0.0025 and not higher than 0.0030.
Δ: the variation is higher than 0.0030 and not higher than 0.0045.
X: the variation is higher than 0.0045.
   [Heat Resistance after Moisture Absorption Test]

The heat resistance after moisture absorption test follows the method specified in JIS C5012 to evaluate the solder-floating thermal resistance of the metal-clad laminate after being exposed to a temperature of 60° C. and a relative humidity (RH) of 60% for 120 hours. Specifically, the metal-clad laminate is subjected to solder-floating in a solder bath at 288° C. for 60 seconds. Subsequently, the metal-clad laminate is visually inspected and examined under an optical microscope (with a magnification of 5× to 1000× being used to assist observation) to identify any defects, such as measling or swelling. If no defects, such as measling or swelling, are observed, the test result is recorded as “◯”, meaning that the laminate passes the heat resistance after moisture absorption test. In case any defects, such as measling or swelling, are identified, the test result is recorded as “X”, meaning that the laminate fails the heat resistance after moisture absorption test.

### [Filling Test]

A glass-fiber epoxy substrate with 588 plated through holes, formed by panel plating, is prepared. The substrate has a thickness of 1.8 mm, and each plating through hole has a diameter of 0.9 mm. A 1078 NE-glass fiber fabric is impregnated or coated with the resin composition and dried at 175° C. for 2 to 5 minutes (B-stage), resulting a semi-cured prepreg (having a resin content of 70% and a thickness of 0.88 mm). Subsequently, two prepregs are placed on one side of the glass-fiber epoxy substrate with through holes and heated to 200° C. to 220° C. at a heating rate of 2° C./min to 4° C./min. The material is then hot-pressed and cured at this temperature under a full pressure of 18 kg/cm² (initial pressure of 8 kg/cm²) for 120 minutes to provide a sample for evaluation. The sample is examined under an optical microscope at 100× magnification to observe cross-sections of the 588 filled plated through holes. The results are assessed according to the following criteria: if all the plated through holes are completely filled or only a few through holes (118 or less) are not completely filled, the filling property of the resin composition is deemed suitable, and the result is recorded as “◯”. However, if the resin composition leaks from the bottom of the through holes or if many of the through holes (more than 118) are not completely filled, the filling property of the resin composition is poor, and the result is recorded as “X”

### [Tackiness Test]

A 1078 NE-glass fiber fabric is impregnated or coated with the resin composition and dried at 175° C. for 2 to 5 minutes (B-stage) to obtain a semi-cured prepreg. Subsequently, multiple semi-cured prepregs are stacked together. The stacking of the prepregs is observed with unaided eyes. If there are no instances of powder spalling or tacky characteristics observed, the result is recorded as “◯”, meaning that the prepreg is not tacky and its processability is good. However, if powder spalling or tackiness is observed, the result is recorded as “X”, meaning that the prepreg is tacky and its processability is poor.

### [Water Absorption Rate Test]

The water absorption rate test follows the IPC-TM650 2.6.2.1 standard. A prepreg is cut into a 2-inch x 2-inch sample and dried before being precisely weighed (to 0.1 mg). Subsequently, the sample is soaked in a distilled water bath at a constant temperature of 23±1.1° C. for 24 hours. After water absorption, the sample is re-weighed (precisely weighted to 0.1 mg). The water absorption rate is calculated as the percentage ratio of “the difference between the weight of the sample after water absorption and the initial dry weight of the sample” to “the initial dry weight of the sample”.

### 4.2. Preparation of Compound

### 4.2.1. Preparation of Compound Having Structure of Formula (I)

### [Preparation of Terminal Modifier VB-CPD]

17.5 g of sodium hydride was washed with hexane to remove mineral oil. Then, the washed sodium hydride was suspended in 350 mL hexane in a 1000 mL round-bottom flask. The flask was filled with an inert atmosphere and cooled to 5° C.

44.0 g of freshly cracked cyclopentadiene (CPD) was added portionwise into the flask with vigorous stirring. After the addition of CPD was complete, the temperature was raised to 60° C. using a reflux system. Afterward, 100 g of 4-vinylbenzyl chloride (VB) was added portionwise into the flask.

Following this, 150 g of deionized water was added with vigorous stirring for 30 minutes to obtain a biphasic mixture. The organic phase of the biphasic mixture was then washed multiple times with 10 wt % of aqueous HCl solution and deionized water.

The organic phase was separated, dried with sodium sulfate, and then subjected to rotary distillation to remove the solvent, resulting in the formation of 4-vinylbenzyl substituted cyclopentadiene (VB-CPD), represented by the following formula.

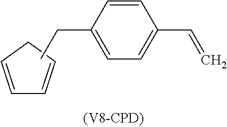

### Synthesis Example A1: Synthesis of SIB Compound

7.80 g of VB-CPD and 10.0 g of 3,3′-dimethyl-5,5′-diethyl-4,4′-diphenylmethanebismaleimide (i.e., a compound represented by formula S1A below) were mixed and dissolved in 20.0 g of dichloromethane solvent. The resulting homogenous solution was allowed to react at room temperature for 30 minutes. Subsequently, the dichloromethane solvent was removed by rotary evaporation at 50° C., resulting in the formation of a compound with the structure represented by formula (I) shown as formula SIB below.

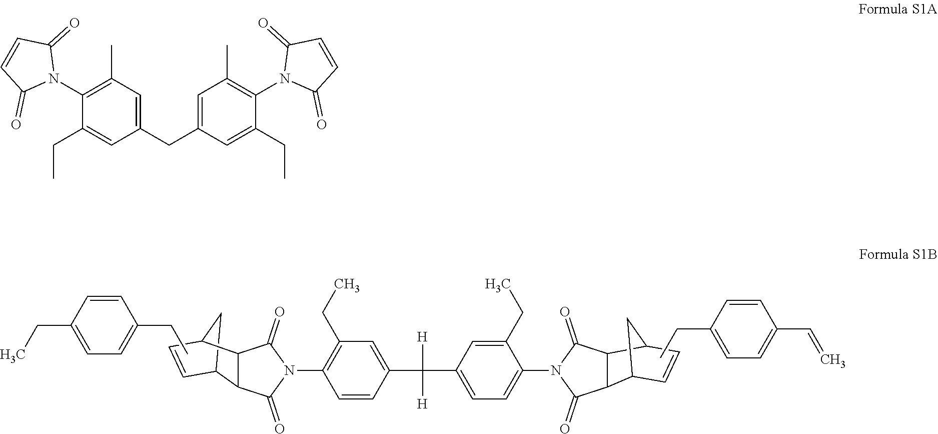

### Synthesis Example A2: Synthesis of S2B Compound

10.0 g of VB-CPD and 10.0 g of a compound represented by formula S2A below were mixed and dissolved in 20.0 g of dichloromethane solvent. The resulting homogenous solution was allowed to react at room temperature for 30 minutes. Subsequently, the dichloromethane solvent was removed by rotary evaporation at 50° C., resulting in the formation of a compound with the structure represented by formula (I) shown as formula S2B below. In formula S2A and S2B, k is an integer of 1 to 5.

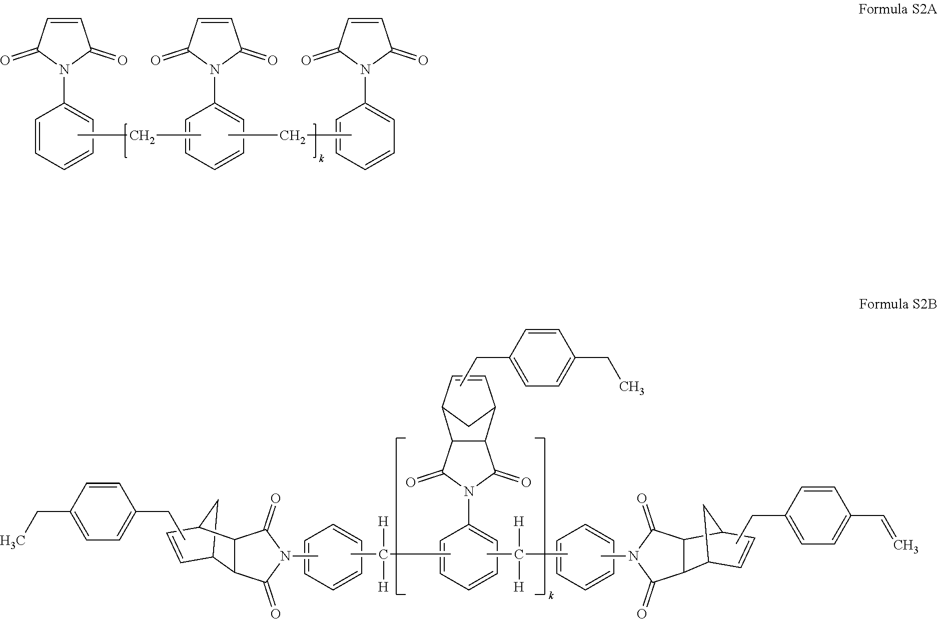

### 4.2.2. Preparation of Component Having Ethylenically Unsaturated Double Bond(s)

### Synthesis Example B1: Synthesis of Polymer 1

Under an inert atmosphere, 29 g of 2,2-bis(4-hydroxy-3-methylphenyl)propane, 18.9 g of 2-phenyl-4,6-dichloropyrimidine, and 21.2 g of potassium carbonate were added to a 500 mL round-bottom flask. Then, 46.7 g of N-methyl-2-pyrrolidone solvent was added, followed by stirring at 100° C. for 6 hours to allow the reaction to proceed. After the reaction completed, the product was cooled to 10° C. At 10° C., 12.7 g of a mixture of 3-(chloromethyl) styrene and 4-(chloromethyl) styrene was slowly added dropwise. The temperature was then raised to 100° C., and the reaction was continued at 100° C. for 4 hours. Subsequently, an additional 61 g of N-methyl-2-pyrrolidone solvent was added and stirred for 30 minutes. Afterward, methanol was added repeatedly for washing and filtration. The solvent was removed via rotary distillation, resulting in polymer 1 represented by formula (II-1) below. In formula (II-1), n is an integer of 1 to 5.

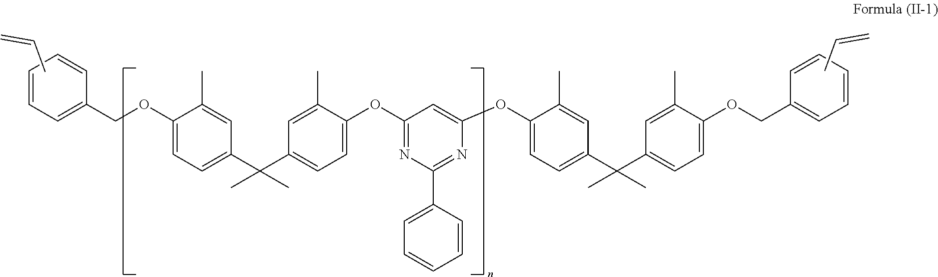

### Synthesis Example B2: Synthesis of Polymer 2

Under an inert atmosphere, 41 g of 1,1-bis(3-methyl-4-hydroxyphenyl)-3,3,5-trimethylcyclohexane, 20 g of 2-phenyl-4,6-dichloropyrimidine, and 22.4 g of potassium carbonate were added to a 500 mL round-bottom flask. Then, 51 g of N-methyl-2-pyrrolidone solvent was added, followed by stirring at 100° C. for 6 hours to allow reaction to proceed. After the reaction completed, the product was cooled to 10° C. At 10° C., 10.4 g of a mixture of 3-(chloromethyl) styrene and 4-(chloromethyl) styrene was slowly added dropwise. The temperature was then raised to 100° C., and the reaction was continued at 100° C. for 4 hours. Subsequently, an additional 67 g of N-methyl-2-pyrrolidone solvent was added and stirred for 30 minutes. Afterward, methanol was added repeatedly for washing and filtration. The solvent was removed via rotary distillation, resulting in polymer 2 represented by formula (II-2) below. In formula (II-2), n is an integer of 1 to 5.

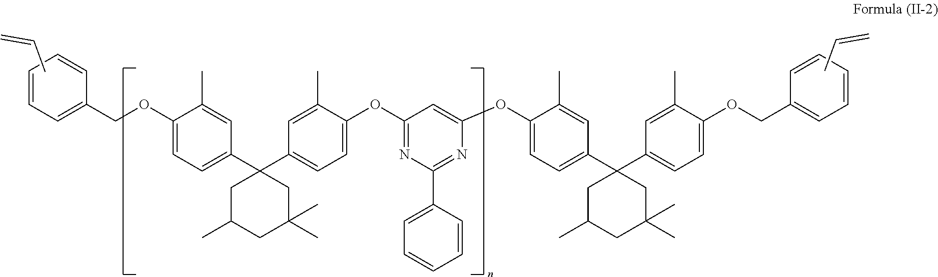

### Synthesis Example B3: Synthesis of Polymer 3

Under an inert atmosphere, 49.2 g of 9,9-bis(4-hydroxy-3-methylphenyl)fluorene, 43.3 g of 2-phenyl-4,6-dichloropyrimidine, and 48.5 g of potassium carbonate were added to a 500 mL round-bottom flask. Then, 236 g of N-methyl-2-pyrrolidone solvent was added, followed by stirring at 100° C. for 6 hours to allow the reaction to proceed. After the reaction completed, the product was cooled to 10° C. At 10° C., 22.6 g of a mixture of 3-(chloromethyl) styrene and 4-(chloromethyl) styrene was slowly added dropwise. The temperature was then raised to 100° C., and the reaction was continued at 100° C. for 4 hours. Subsequently, an additional 72 g of N-methyl-2-pyrrolidone solvent was added and stirred for 30 minutes. Afterward, methanol was added repeatedly for washing and filtration. The solvent was removed via rotary distillation, resulting in polymer 3 represented by formula (II-3) below. In formula (II-3), n is an integer of 1 to 5.

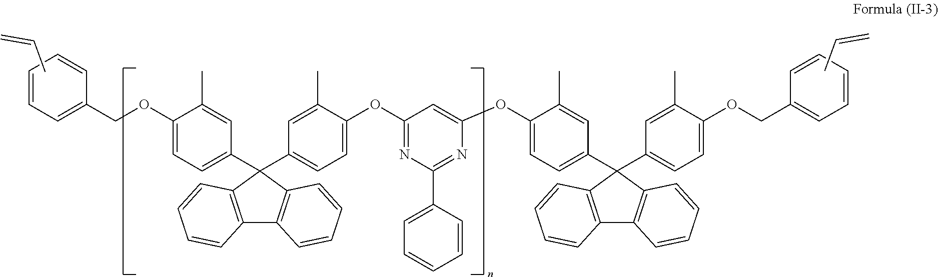

### Synthesis Example B4: Synthesis of Polymer 4

Under an inert atmosphere, 99.6 g of 1,1-bis(3-methyl-4-hydroxyphenyl)-3,3,5-trimethylcyclohexane, 41.7 g of 2-phenyl-4,6-dichloropyrimidine, and 55 g of potassium carbonate were added to a 500 mL round-bottom flask. Then, 89.6 g of N-methyl-2-pyrrolidone solvent was added, followed by stirring at 140° C. for 6 hours to allow reaction to proceed. After the reaction completed, the product was cooled to 10° C. At 10° C., 8.5 g of methacryloyl chloride was slowly added dropwise. The temperature was then raised to 70° C., and the reaction was continued at 70° C. for 4 hours. Subsequently, an additional 515 g of N-methyl-2-pyrrolidone solvent was added and stirred for 30 minutes. Afterward, methanol was added repeatedly for washing and filtration. The solvent was removed via rotary distillation, resulting in polymer 4 represented by formula (II-4) below. In formula (II-4), n is an integer of 1 to 5.

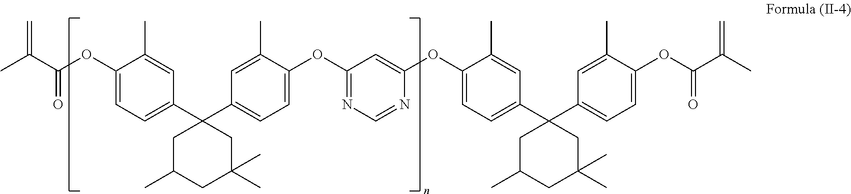

### Synthesis Example B5: Synthesis of Polymer 5

Under an inert atmosphere, 72.0 g of 2,2-bis(4-hydroxy-3-methylphenyl)propane, 71.2 g of 2-phenyl-4,6-dichloropyrimidine, and 50.3 g of potassium carbonate were added to a 1000 mL round-bottom flask. Then, 89.6 g of N-methyl-2-pyrrolidone solvent was added, followed by stirring at 105° C. for 7 hours to allow the reaction to proceed. After the reaction completed, the product was cooled to 10° C. At 10° C., 11.2 g of a mixture of (3-vinylphenyl) methanol and (4-vinylphenyl) methanol was slowly added dropwise. The temperature was then raised to 105° C., and the reaction was continued at 105° C. for 5 hours. Subsequently, an additional 511 g of N-methyl-2-pyrrolidone solvent was added and stirred for 35 minutes. Afterward, methanol was added repeatedly for washing and filtration. The solvent was removed via rotary distillation, resulting in polymer 5 represented by formula (III-1) below. In formula (III-1), m is an integer of 1 to 5.

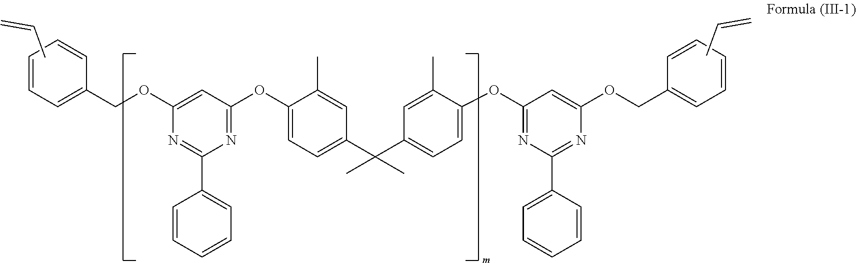

### Synthesis Example B6: Synthesis of Polymer 6

Under an inert atmosphere, 44.9 g of 1,1-bis(3-methyl-4-hydroxyphenyl)-3,3,5-trimethylcyclohexane, 82.6 g of 2-phenyl-4,6-dichloropyrimidine, and 59.2 g of potassium carbonate were added to a 1000 mL round-bottom flask. Then, 45.1 g of 2,2-bis(4-hydroxy-3-allylphenyl)propane and 96.5 g of N-methyl-2-pyrrolidone solvent was added, followed by stirring at 140° C. for 4 hours to allow the reaction to proceed. After the reaction completed, the product was cooled to 10° C. At 10° C., 11.2 g of a mixture of (3-vinylphenyl) methanol and (4-vinylphenyl) methanol was slowly added dropwise. The temperature was then raised to 70° C., and the reaction was continued at 70° C. for 4 hours. Subsequently, an additional 515 g of N-methyl-2-pyrrolidone solvent was added and stirred for 30 minutes. Afterward, methanol was added repeatedly for washing and filtration. The solvent was removed via rotary distillation, resulting in polymer 6 represented by formula (IIIa-1) below. In formula (IIIa-1), m₁ is an integer of 1 to 5, and m₂ is an integer of 1 to 5.

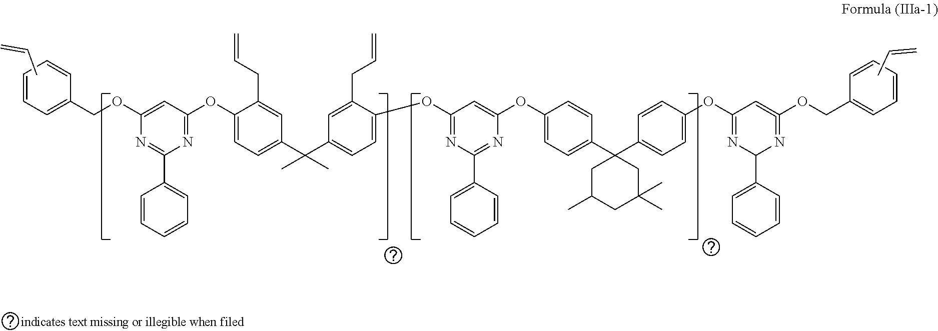

### 4.3. Preparation of Resin Composition

### 4.3.1. List of Raw Materials Used in Examples and Comparative Examples

| Raw material | Description |
|---|---|
| S1B | Compound having a structure of formula (I), prepared in Synthesis Example A1. |
| S2B | Compound having a structure of formula (I), prepared in Synthesis Example A2. |
| Polymer 1 | Component having ethylenically unsaturated double bond(s), prepared in Synthesis |
| | Example B1. |
| Polymer 2 | Component having ethylenically unsaturated double bond(s), prepared in Synthesis |
| | Example B2. |
| Polymer 3 | Component having ethylenically unsaturated double bond(s), prepared in Synthesis |
| | Example B3. |
| Polymer 4 | Component having ethylenically unsaturated double bond(s), prepared in Synthesis |
| | Example B4. |
| Polymer 5 | Component having ethylenically unsaturated double bond(s), prepared in Synthesis |
| | Example B5. |
| Polymer 6 | Component having ethylenically unsaturated double bond(s), prepared in Synthesis |
| | Example B6. |
| SA9000 | Polyphenylene ether resin with unsaturated groups, available from SABIC |
| | Company. |
| OPE-2st | Polyphenylene ether resin with unsaturated groups, available from Mitsubishi gas |
| | chemical Company. |
| Di-L-DAIC | Cross-linking agent, which is |
| | 1,1′-(1,4-butyl)bis(3,5-diallyl-1,3,5-triazine-2,4,6-trione) and has a structure of |
| | 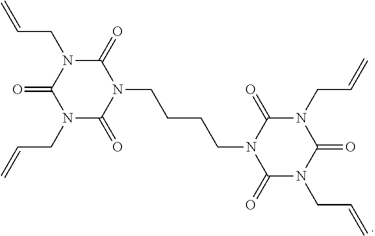 [SMILES: C=CCn1c(=O)n(CC=C)c(=O)n(CCCCn2c(=O)n(CC=C)c(=O)n(CC=C)c2=O)c1=O] |
| TAIC | Cross-linking agent, triallyl isocyanurate, available from Evonik Company. |
| Ricon 257 | Elastomer, styrene-butadiene-divinylbenzene copolymer, available from Cray |
| | Valley Company |
| Perbutyl-P | Catalyst, available from NOF Corporation. |
| SC-5500 | SiO₂ filler, available from Adamatech Company |
| SVC | |

### 4.3.2. Preparation Method

According to the components and proportions shown in Table 1-1, Table 1-2 and Table 2, the components were mixed using a stirrer at room temperature, and methyl ethyl ketone (available from Methyl Company) and toluene (available from Trans Chief Chemical Industry Company) were added. Then, the resultant mixture was stirred at room temperature for 60 to 120 minutes to obtain the resin compositions of Examples E1 to E16 and Comparative Examples CE1 to CE10.

TABLE 1-1

| Unit: parts by weight | | E1 | E2 | E3 | E4 | E5 | E6 | E7 | E8 |
|---|---|---|---|---|---|---|---|---|---|
| Compound having | S1B | 7 | | 35 | | 7 | | 35 | |
| a structure of | S2B | | 7 | | 35 | | 7 | | 35 |
| formula (I) | | | | | | | | | |
| Component | Polymer 1 | 63 | 63 | 35 | 35 | | | | |
| having | Polymer 2 | | | | | 63 | 63 | 35 | 35 |
| ethylenically | Polymer 3 | | | | | | | | |
| unsaturated | Polymer 4 | | | | | | | | |
| double bond(s) | Polymer 5 | | | | | | | | |
| | Polymer 6 | | | | | | | | |
| Cross-linking | Di-L-DAIC | 18 | 18 | 18 | 18 | 18 | 18 | 18 | 18 |
| agent | TAIC | 15 | 15 | 15 | 15 | 15 | 15 | 15 | 15 |
| Elastomer | Ricon 257 | 30 | 30 | 30 | 30 | 30 | 30 | 30 | 30 |
| Catalyst | Perbutyl P | 1 | 1 | 1 | 1 | 1 | 1 | 1 | 1 |
| Filler | SC-5500 SVC | 100 | 100 | 100 | 100 | 100 | 100 | 100 | 100 |

TABLE 1-2

| Unit: parts by weight | | E9 | E10 | E11 | E12 | E13 | E14 | E15 | E16 |
|---|---|---|---|---|---|---|---|---|---|
| Compound having | S1B | 7 | | 35 | | | 7 | 7 | 7 |
| a structure of | S2B | | 7 | | 35 | 65 | | | |
| formula (I) | | | | | | | | | |
| Component | Polymer 1 | | | | | | | | |
| having | Polymer 2 | | | | | | | | |
| ethylenically | Polymer 3 | 63 | 63 | 35 | 35 | 95 | | | |
| unsaturated | Polymer 4 | | | | | | 63 | | |
| double bond(s) | Polymer 5 | | | | | | | 63 | |
| | Polymer 6 | | | | | | | | 63 |
| Cross-linking | Di-L-DAIC | 18 | 18 | 18 | 18 | | | | |
| agent | TAIC | 15 | 15 | 15 | 15 | | 33 | 33 | 33 |
| Elastomer | Ricon 257 | 30 | 30 | 30 | 30 | | 30 | 30 | 30 |
| Catalyst | Perbutyl P | 1 | 1 | 1 | 1 | 1 | 1 | 1 | 1 |
| Filler | SC-5500 SVC | 100 | 100 | 100 | 100 | 100 | 100 | 100 | 100 |

TABLE 2

| Unit: parts by weight | | CE1 | CE2 | CE3 | CE4 | CE5 | CE6 | CE7 | CE8 | CE9 | CE10 |
|---|---|---|---|---|---|---|---|---|---|---|---|
| Compound having | S1B | 7 | | 7 | | | | | 70 | 103 | |
| a structure of | S2B | | 35 | | 35 | | | | | | |
| formula (I) | | | | | | | | | | | |
| Component | Polymer 1 | | | | | 63 | | | | | |
| having | Polymer 2 | | | | | | 63 | | | | |
| ethylenically | Polymer 3 | | | | | | | 63 | | | |
| unsaturated | Polymer 4 | | | | | | | | | | |
| double bond(s) | Polymer 5 | | | | | | | | | | |
| | Polymer 6 | | | | | | | | | | |
| Polyphenylene | SA9000 | 63 | 35 | | | | | | | | 63 |
| ether resin with | OPE-2st | | | 99 | 55 | | | | | | |
| unsaturated | | | | | | | | | | | |
| groups | | | | | | | | | | | |
| Cross-linking | Di-L-DAIC | 18 | 18 | 18 | 18 | 18 | 18 | 18 | 18 | | |
| agent | TAIC | 15 | 15 | 15 | 15 | 15 | 15 | 15 | 15 | | 33 |
| Elastomer | Ricon 257 | 30 | 30 | 30 | 30 | 30 | 30 | 30 | 30 | 30 | 30 |
| Catalyst | Perbutyl P | 1 | 1 | 1 | 1 | 1 | 1 | 1 | 1 | 1 | 1 |
| Filler | SC-5500 SVC | 100 | 100 | 100 | 100 | 100 | 100 | 100 | 100 | 100 | 100 |

### 4.4. Preparation and Property Measurements of Metal-Clad Laminate

Metal-clad laminates of Examples E1 to E16 and Comparative Examples CE1 to CE10 were individually prepared using the respective prepared resin compositions. Initially, glass fiber cloths (Model No.: 1078; thickness: 0.043 mm) were impregnated with the resin compositions of Examples E1 to E16 and Comparative Examples CE1 to CE10 using roll coaters. The thicknesses of these impregnated glass fiber cloths were carefully controlled. Subsequently, the impregnated glass fiber cloths underwent drying in an oven at 175° C. for 2 minutes to 5 minutes, resulting in the production of semi-cured (B-stage) prepregs (with a resin content of the prepreg: 70%). Afterward, multiple prepregs were superimposed, and two sheets of 5-ounce copper foils were superimposed on the respective two surfaces of the outermost layers. The superimposed objects were then subjected to a high-temperature curing process using a hot pressing under the following conditions: heating to 200° C. to 220° C. at a heating rate of 2° C./min to 4° C./min, and hot-pressing at 200° C. to 220° C. for 120 minutes under a full pressure of 18 kg/cm² (with an initial pressure of 8 kg/cm²).

The properties of the metal-clad laminates of Examples E1 to E16 and Comparative Examples CE1 to CE10, including glass transition temperature (Tg), coefficient of thermal expansion (z-CTE), dielectric properties, aging resistance, heat resistance after moisture absorption, processing stability (including filling and tackiness properties), peeling strength, and water absorption rate, were tested according to the aforementioned testing methods. The results are tabulated in Table 3-1, Table 3-2 and Table 4.

TABLE 3-1

| | E1 | E2 | E3 | E4 | E5 | E6 | E7 | E8 |
|---|---|---|---|---|---|---|---|---|
| Peeling strength | 4.6 | 4.5 | 4.8 | 4.8 | 4.6 | 4.7 | 4.9 | 4.8 |
| (lbf/in) | | | | | | | | |
| Tg (° C.) | 234 | 232 | 246 | 248 | 230 | 233 | 245 | 249 |
| z-CTE (%) | 1.7 | 1.6 | 1.4 | 1.4 | 1.6 | 1.5 | 1.4 | 1.4 |
| Dk₀ | 2.98 | 2.99 | 3.07 | 3.11 | 3.00 | 2.98 | 3.08 | 3.10 |
| Df₀ | 0.00118 | 0.00119 | 0.00127 | 0.00129 | 0.00116 | 0.00118 | 0.00125 | 0.00127 |
| Thermal- | ⊚ | ⊚ | ⊚ | ⊚ | ⊚ | ⊚ | ⊚ | ⊚ |
| oxidative aging | | | | | | | | |
| resistance (ΔDf₁) | | | | | | | | |
| Damp-heat aging | ⊚ | ⊚ | ⊚ | ⊚ | ⊚ | ⊚ | ⊚ | ⊚ |
| resistance (ΔDf₂) | | | | | | | | |
| Heat resistance | ◯ | ◯ | ◯ | ◯ | ◯ | ◯ | ◯ | ◯ |
| after moisture | | | | | | | | |
| absorption | | | | | | | | |
| Filling test | ◯ | ◯ | ◯ | ◯ | ◯ | ◯ | ◯ | ◯ |
| Tackiness test | ◯ | ◯ | ◯ | ◯ | ◯ | ◯ | ◯ | ◯ |
| Water absorption | 0.09 | 0.10 | 0.12 | 0.11 | 0.08 | 0.09 | 0.11 | 0.12 |
| rate | | | | | | | | |

TABLE 3-2

| | E9 | E10 | E11 | E12 | E13 | E14 | E15 | E16 |
|---|---|---|---|---|---|---|---|---|
| Peeling strength | 3.7 | 3.9 | 4.4 | 4.5 | 3.8 | 4.3 | 4.0 | 4.7 |
| (lbf/in) | | | | | | | | |
| Tg (° C.) | 257 | 254 | 270 | 265 | 251 | 221 | 230 | 241 |
| z-CTE (%) | 1.3 | 1.3 | 1.0 | 1.1 | 1.3 | 1.6 | 1.9 | 1.2 |
| Dk₀ | 2.97 | 3.01 | 3.11 | 3.10 | 2.91 | 2.99 | 3.11 | 2.95 |
| Df₀ | 0.00111 | 0.00110 | 0.00122 | 0.00123 | 0.00108 | 0.00120 | 0.00125 | 0.00115 |
| Thermal- | ⊚ | ⊚ | ⊚ | ⊚ | ⊚ | ⊚ | ⊚ | ⊚ |
| oxidative aging | | | | | | | | |
| resistance (ΔDf₁) | | | | | | | | |
| Damp-heat aging | ⊚ | ⊚ | ⊚ | ⊚ | ⊚ | ⊚ | ⊚ | ⊚ |
| resistance (ΔDf₂) | | | | | | | | |
| Heat resistance | ◯ | ◯ | ◯ | ◯ | ◯ | ◯ | ◯ | ◯ |
| after moisture | | | | | | | | |
| absorption | | | | | | | | |
| Filling test | ◯ | ◯ | ◯ | ◯ | ◯ | ◯ | ◯ | ◯ |
| Tackiness test | ◯ | ◯ | ◯ | ◯ | ◯ | ◯ | ◯ | ◯ |
| Water absorption | 0.08 | 0.09 | 0.10 | 0.10 | 0.09 | 0.09 | 0.12 | 0.08 |
| rate | | | | | | | | |

TABLE 4

| | CE1 | CE2 | CE3 | CE4 | CE5 | CE6 | CE7 | CE8 | CE9 | CE10 |
|---|---|---|---|---|---|---|---|---|---|---|
| Peeling | 3.9 | 4.1 | 4.1 | 4.3 | 4.1 | 4.2 | 3.6 | 3.9 | 4.2 | 3.5 |
| strength | | | | | | | | | | |
| (lbf/in) | | | | | | | | | | |
| Tg (° C.) | 210 | 231 | 215 | 236 | 175 | 180 | 223 | 248 | 240 | 199 |
| z-CTE (%) | 3.1 | 2.8 | 3.0 | 2.7 | 3.6 | 3.4 | 3.1 | 2.5 | 2.7 | 3.2 |
| Dk₀ | 3.12 | 3.10 | 3.11 | 3.09 | 3.02 | 3.01 | 2.98 | 3.04 | 3.03 | 3.15 |
| Df₀ | 0.00193 | 0.00184 | 0.00189 | 0.00181 | 0.00160 | 0.00158 | 0.00150 | 0.00170 | 0.00169 | 0.00221 |
| Thermal- | X | Δ | X | Δ | ◯ | ◯ | ◯ | Δ | Δ | X |
| oxidative | | | | | | | | | | |
| aging | | | | | | | | | | |
| resistance | | | | | | | | | | |
| (ΔDf₁) | | | | | | | | | | |
| Damp-heat | X | Δ | X | Δ | ◯ | ◯ | ◯ | Δ | Δ | X |
| aging | | | | | | | | | | |
| resistance | | | | | | | | | | |
| (ΔDf₂) | | | | | | | | | | |
| Heat | ◯ | ◯ | ◯ | ◯ | ◯ | ◯ | ◯ | ◯ | ◯ | X |
| resistance | | | | | | | | | | |
| after | | | | | | | | | | |
| moisture | | | | | | | | | | |
| absorption | | | | | | | | | | |
| Filling test | ◯ | ◯ | ◯ | ◯ | ◯ | ◯ | ◯ | ◯ | ◯ | ◯ |
| Tackiness | ◯ | ◯ | ◯ | ◯ | ◯ | ◯ | ◯ | ◯ | ◯ | X |
| test | | | | | | | | | | |
| Water | 0.27 | 0.25 | 0.26 | 0.24 | 0.17 | 0.18 | 0.19 | 0.23 | 0.21 | 0.30 |
| absorption | | | | | | | | | | |
| rate | | | | | | | | | | |

As shown in Tables 3-1, 3-2 and 4, the metal-clad laminates prepared from the resin compositions of the present invention has outstanding peeling strength, glass transition temperature (Tg), coefficient of thermal expansion (z-CTE), dielectric properties, aging resistance, heat resistance after moisture absorption, processing stability (filling and tackiness properties), and water absorption rate. By contrast, the comparative examples show that if the resin composition does not comprise both the compound (A) having a structure of formula (I) and the component (B) having ethylenically unsaturated double bond(s), the obtained metal-clad laminate cannot simultaneously have the aforementioned outstanding properties.

In particular, the comparison between Examples E1, E5 and E9 versus Comparative Examples CE1 and CE3, as well as between Examples E4, E8 and E12 versus Comparative Examples CE2 and CE4, demonstrate that when the same amount of compound (A) having a structure of formula (I) is used, the combined use of the component (B) having ethylenically unsaturated double bond(s) in the present invention provides superior efficacy compared to the combined use of unsaturated group-containing polyphenylene ethers. Comparative Examples CE5-CE7 and Comparative Examples CE8-CE9 respectively show that the inventive efficacy cannot be achieved when solely using the compound (A) having a structure of formula (I) or the component (B) having ethylenically unsaturated double bond(s). Comparative Example 10 shows that without both the compound (A) having a structure of formula (I) and the component (B) having ethylenically unsaturated double bond(s), the resulting metal-clad laminate not only fails to attain the inventive efficacy but also exhibits the poorest properties.

The above examples illustrate the principle and efficacy of the present invention and show the inventive features thereof. People skilled in this field may proceed with a variety of modifications and replacements based on the disclosures and suggestions of the invention as described without departing from the principle thereof. Therefore, the scope of protection of the present invention is as defined in the claims as appended.

What is claimed is:

1. A resin composition, which comprises:
(A) a compound having a structure of formula (I); and 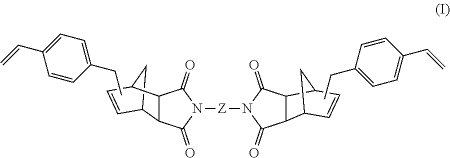
(B) a component having ethylenically unsaturated double bond(s), which is selected from the group consisting of a compound having a structure of formula (II), a compound having a structure of formula (III), and combinations thereof, 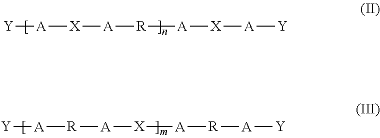
wherein,
Z is a divalent organic group;
each A is independently —O—, —S—, or —N(R₁)—, wherein R₁ is H, a C1-C20 hydrocarbyl, a C1-C20 halogenated hydrocarbyl, or a group formed by substituting a part of the C1-C20 hydrocarbyl or halogenated hydrocarbyl with at least one of O and S;
each R is independently an unsubstituted or substituted divalent nitrogen-containing heteroaromatic ring;
each X is independently 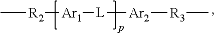
wherein R₂ and R₃ are independently a direct bond or a C1-C4 alkylene, Ar₁ and Ar₂ are independently an unsubstituted or substituted divalent aromatic hydrocarbyl, L is a direct bond, —O—, —S—, —N(R₄)—, —C(O)—O—, —C(O)—NH—, —S(O)—, S(O)₂—, —P(O)—, a C1-C20 alkylene, a C1-C20 halogenated alkylene, a divalent cardo structure, or an unsubstituted or substituted divalent C5-C30 alicyclic hydrocarbyl, R₄ is H, a C1-C20 hydrocarbyl, or a C1-C20 halogenated hydrocarbyl, p is an integer of 0-5, and each Ar₁ can be identical or different when p is 2 or more;
each Y is independently a group containing ethylenically unsaturated double bond(s);
m is an integer of 1-100; and
n is an integer of 1-100.

2. The resin composition of claim 1, wherein the component (B) having ethylenically unsaturated double bond(s) is selected from the group consisting of a compound having a structure of formula (IIa), a compound having a structure of formula (IIIa), and combinations thereof, 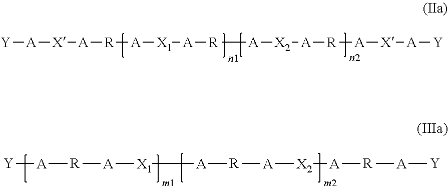
wherein,
R, A and Y of formulas (IIa) and (IIIa) have the same definition as in formulas (II) and (III);
X₁ and X₂ each have the same definition as X of formulas (II) and (III), and X₁ and X₂ are different from each other;
X′ is X₁ or X₂;
n₁ and n₂ are independently an integer of 0-50, and a sum of n₁ and n₂ is less than 100; and
m₁ and m₂ are independently an integer of 0-50, with the proviso that m₁ and m₂ are not 0 at the same time.

3. The resin composition of claim 1, wherein Z in formula (I) is 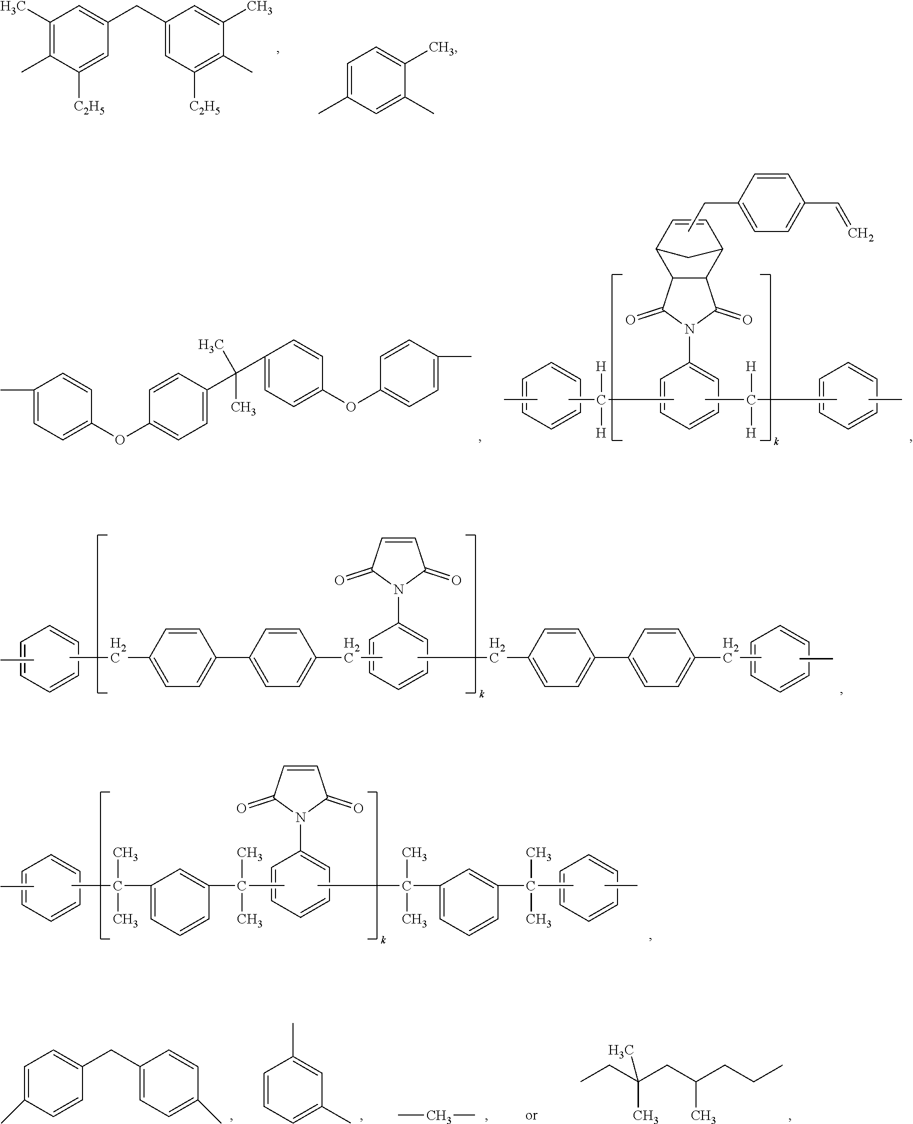
wherein k is an integer of 1-5.

4. The resin composition of claim 1, wherein R in formulas (II) and (III) is each independently an unsubstituted or substituted divalent nitrogen-containing heteroaromatic ring, and the nitrogen-containing heteroaromatic ring is a pyrrole ring, a pyridine ring, a pyrimidine ring, a pyridazine ring, a pyrazine ring, a triazine ring, a quinoline ring, an isoquinoline ring, a quinoxaline ring, a phthalazine ring, a quinazoline ring, a naphthyridine ring, a carbazole ring, an acridine ring, or a phenazine ring.

5. The resin composition of claim 1, wherein R in formulas (II) and (III) is each independently an unsubstituted or substituted divalent nitrogen-containing heteroaromatic ring, and the nitrogen-containing heteroaromatic ring is a pyridine ring, a pyrimidine ring, a pyridazine ring, a pyrazine ring, or a triazine ring.

6. The resin composition of claim 1, wherein Ar₁ and Ar₂ are independently an unsubstituted or substituted divalent aromatic hydrocarbyl, wherein the divalent aromatic hydrocarbyl is phenylene, naphthylene, anthracenylene, or biphenylene, and each Ar₁ can be identical or different.

7. The resin composition of claim 1, wherein L is a C1-C10 alkylene, a C1-C10 halogenated alkylene, 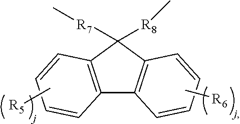
or an unsubstituted or substituted divalent C5-C30 alicyclic hydrocarbyl,
wherein,
R₅ and R₆ are each independently F or a C1-C20 linear hydrocarbyl;
R₇ and R₈ are independently a direct bond, an unsubstituted or substituted linear hydrocarbylene, or an unsubstituted or substituted alicyclic hydrocarbylene; and
j is an integer of 0-4.

8. The resin composition of claim 1, wherein Y in formulas (II) and (III) is each independently 2-isopropenylphenyl, 3-isopropenylphenyl, 4-isopropenylphenyl, 2-allylphenyl, 3-allylphenyl, 4-allylphenyl, 2-methoxy-4-allylphenyl, 4-(1-propenyl)-2-methoxyphenyl, 4-vinylbenzyl, 3-vinylbenzyl, 2-vinylbenzyl, allyl, acryloyl, methacryloyl, or methallyl.

9. The resin composition of claim 1, wherein the weight ratio of the compound (A) having a structure of formula (I) to the component (B) having ethylenically unsaturated double bond(s) is 1:9 to 1:1.

10. The resin composition of claim 1, further comprising an additive selected from the group consisting of a catalyst, a cross-linking agent, an elastomer, a filler, a dispersing agent, a toughener, a viscosity modifier, a flame retardant, a plasticizer, a coupling agent, and combinations thereof.

11. The resin composition of claim 10, wherein the catalyst is selected from the group consisting of dicumyl peroxide, tert-butyl peroxybenzoate, di-tert-amyl peroxide (DTAP), isopropylcumyl-tert-butyl peroxide, tert-butylcumylperoxide, di(isopropylcumyl) peroxide, di-tert-butyl peroxide, α,α′-bis(tert-butylperoxy)diisopropyl benzene, benzoyl peroxide (BPO), 1,1-bis(tert-butylperoxy)-3,3,5-trimethylcyclohexane, 4,4-di(tert-butylperoxy)butyl valerate, 2,5-dimethyl-2,5-di(tert-butylperoxy)hexane, 2,5-dimethyl-2,5-di(tert-butylperoxy)-3-hexyne, and combinations thereof.

12. The composition of claim 10, wherein the cross-linking agent is selected from the group consisting of a polyfunctional allylic compound, a polyfuctional acrylate, a polyfuctional acrylamide, a polyfunctional styrenic compound, and combinations thereof.

13. The resin composition of claim 10, wherein the elastomer is selected from the group consisting of polybutadiene, a styrene-butadiene copolymer, a styrene-butadiene-divinylbenzene copolymer, polyisoprene, a styrene-isoprene copolymer, an acrylonitrile-butadiene copolymer, an acrylonitrile-butadiene-styrene copolymer, a functionally modified derivative of the preceding compounds, and combinations thereof.

14. The resin composition of claim 10, wherein the filler is selected from the group consisting of silica, aluminum oxide, magnesium oxide, magnesium hydroxide, calcium carbonate, talc, clay, aluminum nitride, boron nitride, aluminum hydroxide, silicon aluminum carbide, silicon carbide, sodium carbonate, titanium dioxide, zinc oxide, zirconium oxide, quartz, diamond, diamond-like carbon, graphite, calcined kaolin, pryan, mica, hydrotalcite, polytetrafluoroethylene powders, glass beads, ceramic whiskers, carbon nanotubes, nanosized inorganic powders, and combinations thereof.

15. A prepreg, which is prepared by impregnating a substrate with the resin composition of claim 1 or by coating the resin composition of claim 1 onto a substrate and drying the impregnated or coated substrate.

16. A metal-clad laminate, which is prepared by laminating the prepreg of claim 15 and a metal foil.

17. A printed circuit board, which is prepared from the metal-clad laminate of claim 16.

18. A metal-clad laminate, which is prepared by coating the resin composition of claim 1 onto a metal foil and drying the coated metal foil.

19. A printed circuit board, which is prepared from the metal-clad laminate of claim 18.
